(19) United States
(12) Patent Application Publication
(10) Pub. No.: US 2003/0042558 A1
(43) Pub. Date: Mar. 6, 2003

(54) Nonvolatile semiconductor memory device having erasing characteristic improved

(76) Inventors: Mitsuhiro Noguchi, Yokohama-shi (JP); Akira Goda, Yokohama-shi (JP); Shigehiko Saida, Yokohama-shi (JP); Masayuki Tanaka, Yokohama-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/230,092

(22) Filed: Aug. 29, 2002

(30) Foreign Application Priority Data
Aug. 31, 2001 (JP) 2001-264754

(51) Int. Cl. H01L 29/76

(52) U.S. Cl. 257/406

(57) ABSTRACT

A memory cell which allows information to be written or erased electrically. The memory cell includes a gate insulation film including three layers, i.e., a first insulation layer, an electric charge accumulating layer and a second insulation layer and a gate electrode formed on the gate insulation film. The electric charge accumulating layer is composed of a silicon nitride film or silicon oxynitride film. The first and second insulation layers are composed of a silicon oxide film or silicon oxynitride film containing more oxygen composition than the electric charge accumulating layer. The thickness of the second insulation layer is more than 5 nm. The gate electrode is formed of a p-type semiconductor containing p-type impurity.

### CROSS-REFERENCE TO RELATED APPLICATIONS

This application is based upon and claims the benefit of priority from the prior Japanese Patent Application No. 2001-264754, filed Aug. 31, 2001, the entire contents of which are incorporated herein by reference.

### BACKGROUND OF THE INVENTION

1. Field of the Invention

The present invention relates to a MONOS type nonvolatile semiconductor memory device in which the erasing characteristic of a memory cell thereof is improved so as to achieve higher integration.

2. Description of the Related Art

Such a nonvolatile semiconductor memory (EEPROM) has been developed in which digital bit information is stored by implanting electric charge into an electric charge accumulating layer with tunnel current from a channel region through an insulation film and then information is read out based on conductance of the MOSFET depending on the amount of that electric charge. Particularly the MONOS memory using a SiN film as its electric charge accumulating layer has been studied aggressively because it may write in or erase with a lower voltage than a memory employing a floating gate formed of polycrystalline silicon.

The MONOS memory has been disclosed in, for example, U.S. Pat. No. 6,137,718 (issued Oct. 24, 2000) and U.S. Pat. No. 6,040,995 (issued Mar. 21, 2000). Each of the MONOS memories disclosed in these publications has such a structure in which a semiconductor substrate, a silicon oxide film (first silicon oxide film) allowing electric charge to pass intentionally, a silicon nitride film (electric charge accumulating layer), a silicon oxide film (second silicon oxide film) for blocking current between the nitride film and a gate electrode, and a gate electrode are overlaid in this order.

Particularly according to the U.S. Pat. No. 6,137,718, in order to maintain the holding characteristic for accumulated electric charges and reduce erasing time thereof, a difference in film thickness between the second silicon oxide film and the first silicon oxide film is kept between 0.5 nm and 1 nm, the film thickness of each of the second silicon oxide film and the first silicon oxide film is kept to 3 nm or more and a p-type gate electrode material in which p-type impurity of 1×10²⁰ (cm⁻³) or more is added is employed as its gate electrode.

However, because the difference in film thickness between the second silicon oxide film and the first silicon oxide film is so small in this example, implantation of electrons from the gate electrode into the electric charge accumulating layer occurs when the erasing action is carried out using implantation of positive holes from the semiconductor substrate into the electric charge accumulating layer.

Thus, if erasing voltage applied to the gate electrode is increased, the amount of increase in the implanting amount of electrons increases up to substantially the same level as the pouring amount of positive holes. For the reason, there is such a problem that an erasing threshold value never drops below a predetermined value, so that it does not drop sufficiently low. That is, it is impossible to secure a sufficient difference between the write threshold value and the erasing threshold value.

Further, in case of forming MOSFET on the same substrate by use of the same gate electrode material as the MONOS memory using the p type gate electrode material, if the p-type impurity density of the gate electrode is as high as 1×10²⁰ (cm⁻³) or more, there is produced another problem.

If the p-type impurity density of the gate electrode is as high as 1×20²⁰ (cm⁻³) or more, when high-temperature heating step is added after the gate electrode is deposited, as reported in “T. Aoyama, H. Arimoto, K. Horiuchi, “Boron diffusion in SiO₂ Involving High-Concentration Effects”, Extended Abstracts of the 2000 International Conference on Solid State Physics and Materials, Sendai, 2000, pp. 190-191”, the p type impurity added to the gate is abnormally diffused in the silicon oxide film. As a result, there occurs a problem that the quality of the silicon oxide film is deteriorated and particularly if the silicon oxide film is 20 nm or less, as reported already, the p-type impurity oozes over the semiconductor substrate of the MOSFET. In this case, the threshold voltage of the MOSFET becomes impossible to control and particularly, the p-type MOSFET having a low threshold cannot be produced.

Further, in case where positive holes are implanted through the tunnel current, there occurs a problem that the positive current decreases so that the erasing time increases, because the lower limit of the film thickness of the first silicon oxide film is as large as 3 nm.

As described above, the conventional MONOS memory cell has the problem that if the erasing voltage is increased in order to execute high-speed erasing, the erasing threshold value does not drop sufficiently.

Further, because the lower limit of the film thickness of the first silicon oxide film is as large as 3 nm, there occurs such a problem that the positive hole current decreases so as to increase the erasing time.

Therefore, the above-described problems are desired to be solved.

### BRIEF SUMMARY OF THE INVENTION

According to an aspect of the present invention, there is provided a semiconductor memory cell allowing information to be written or erased electrically comprises a gate insulation film having a multi-layer structure including three layers, the gate insulation film being included a first insulation layer, an electric charge accumulating layer and a second insulation layer, the electric charge accumulating layer being included a silicon nitride film or a silicon oxynitride film, the first insulation layer and second insulation layer being included a silicon oxide film or a silicon oxynitride film containing more oxygen composition than the electric charge accumulating layer, the second insulation layer being more than 5 nm in thickness; a control electrode formed on the gate insulation film and included a p-type semiconductor containing p-type impurity.

### BRIEF DESCRIPTION OF THE SEVERAL VIEWS OF THE DRAWING

FIG. 1 is a sectional view showing the element structure of a MONOS memory cell according to a first embodiment of the present invention;

FIG. 2 is a band diagram at the time of data erase in the MONOS memory cell of FIG. 1;

FIG. 3 is a characteristic graph showing the relation between electric fields Eox1 and Eox2 applied to a first insulation layer and a second insulation layer of the MONOS memory cell of FIG. 1;

FIG. 4 is a characteristic graph showing the relation between the electric fields Eox1 and Eox2 applied to the first insulation layer and the second insulation layer assuming that electric charge center-of-gravity is located on an interface between the first insulation layer and the electric charge accumulating layer in the MONOS memory of FIG. 1;

FIG. 5 is a characteristic graph showing the relation between the erasing gate voltage and erase saturation flat band voltage in the MONOS memory of FIG. 1;

FIG. 6 is a band diagram at the time of data erasing in the MONOS memory cell of FIG. 1;

FIG. 7 is a sectional view showing the element structure of a MONOS memory cell according to a modification of the first embodiment;

FIG. 8 is a sectional view showing the element structure of a MONOS memory cell according to a second embodiment of the present invention;

FIG. 9 is a sectional view showing the element structure of a MONOS memory cell according to a modification of the second embodiment;

FIG. 10 is a sectional view showing the element structure of a semiconductor memory device according to a third embodiment of the present invention;

FIGS. 11A to 11G are sectional views showing manufacturing steps upon manufacturing the semiconductor memory device according to the third embodiment;

FIGS. 12A to 12I are sectional views showing manufacturing steps according to a modification of the third embodiment;

FIGS. 13A and 13B are sectional views showing the element structure of a semiconductor memory device according to a fourth embodiment of the present invention;

FIGS. 14A to 14L are sectional views showing the manufacturing steps for the semiconductor memory device according to the fourth embodiment;

FIGS. 15A and 15B are a circuit diagram and a plan view of a semiconductor memory device according to a fifth embodiment of the present invention, respectively;

FIG. 16 is a sectional view showing the element structure of the semiconductor memory device according to the fifth embodiment;

FIG. 17 is a sectional view different from that shown in FIG. 16, of the semiconductor memory device of the fifth embodiment;

FIGS. 18A and 18B are a circuit diagram and a plan view of a semiconductor memory device according to a sixth embodiment of the present invention;

FIGS. 19A and 19B are other sectional views the semiconductor memory device of the sixth embodiment;

FIGS. 20A and 20B are a circuit diagram and a plan view of the semiconductor memory device according to a seventh embodiment of the present invention; and

FIGS. 21A and 21B are other sectional views of the semiconductor memory device of the seventh embodiment.

### DETAILED DESCRIPTION OF THE INVENTION

Hereinafter, the present invention will be described in detail with a plurality of embodiments to the accompanying drawings.

(First embodiment)

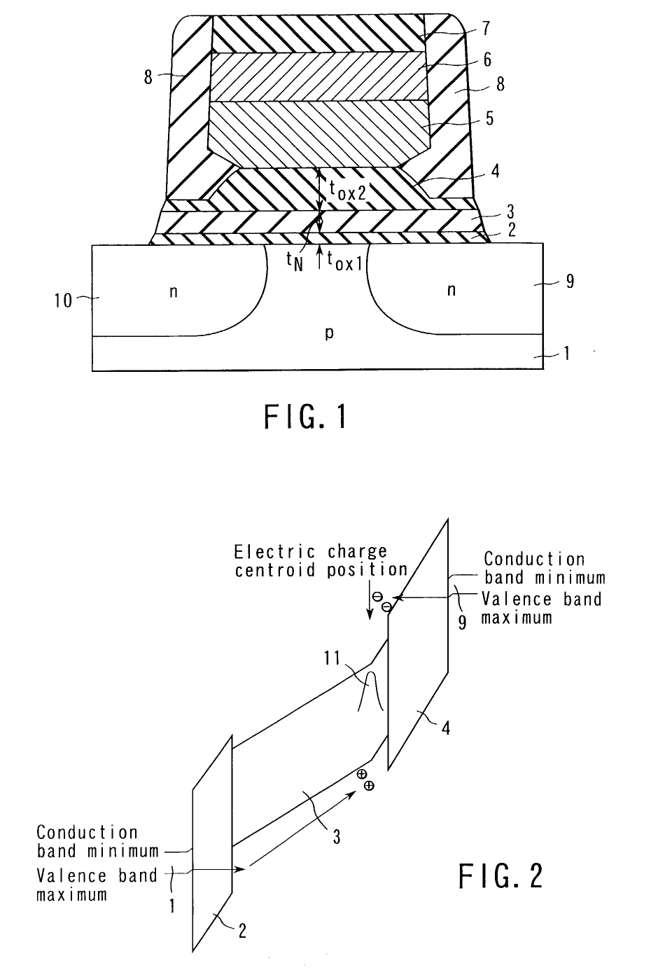

FIG. 1 is a sectional view showing the element structure of the MONOS memory cell of the first embodiment. The memory cell of the embodiment is different from the conventional one in that the thickness of the second insulation layer is more than 5 nm and the gate electrode is composed of a p-type semiconductor.

Referring to FIG. 1, a first insulation layer 2 composed of a silicon oxide film or oxynitride film having a thickness of, for example, 0.5 to 10 nm is formed on a p type silicon semiconductor region 1 in which the density of impurity such as boron, indium is 10¹⁴ (cm⁻³) to 10¹⁹ (cm⁻³). Here assume that the thickness of the flat portion of the first insulation layer 2 is tox1 and that relative permittivity thereof to the silicon oxide film is εox1.

Further, an electric charge accumulating layer 3 composed of, for example, a silicon nitride film is formed on the first insulation layer 2 in the thickness of 3 to 50 nm. Assume that the thickness of the flat portion of the electric charge accumulating layer 3 is tN and that the relative permittivity to the silicon oxide film is εN. A gate electrode 5, composed of a polycrystalline silicon layer to which for example, boron is added as impurity in a range of 1×10¹⁹ (cm⁻³) to 1×10²¹ (cm⁻³), is formed thereon via a block insulation film (second insulation layer) 4 composed of a silicon oxide film or oxynitride film having a thickness of more than 5 and 30 nm or less. Then, the first insulation layer 2, the electric charge accumulating layer 3 and the second insulation layer 4 construct a gate insulation film having an overlaid structure composed of three layers of ONO film.

Preferably, the boron density in the gate electrode (control electrode) 5 composed of a polycrystalline silicon layer is 1×10²⁰ (cm⁻³) or less in order to prevent abnormal diffusion of boron in the silicon oxide film and stabilize the threshold value of the p type MOS field transistor formed at the same time. Further, preferably, the boron density of the gate electrode 5 composed of a polycrystalline silicon layer is set to 1×10¹⁹ (cm⁻³) or more in order to reduce electric field applied to the ONO film due to depletion of the gate electrode thereby preventing the erasing time from increasing.

Here assume that the thickness of the flat portion of the second insulation layer 4 is Tox2 and that the relative permittivity to the silicon oxide film is εox2.

The MONOS memory cell of the embodiment is different from the conventional one in that the film thickness tox2 of the second insulation layer 4 is more than 5 nm. Here, the phenomenon that the threshold value of erasing state does not drop below a predetermined value is referred to as erasing threshold value saturation phenomenon for convenience for following description. In order to prevent saturation of the erasing threshold value, electron current which tunnels through the second insulation layer 4 at the time of erasing is preferred to be decreased. Here, when tox2 is more than 5 nm, if electric field is applied to the second insulation layer 4 at the time of erasing, not direct tunnel current but Fowler-Nordheim (FN) current flows thereby making it possible to keep small current flowing to the second insulation layer 4. Therefore, the second insulation layer 4 is desired to be sufficiently thick.

When a silicon oxide film or silicon oxynitride is used as the first insulation layer, the height of barrier to positive hole is larger by 1 eV or more than the height of barrier to electron. Therefore, the tunnel phenomenon cannot be obtained until the first insulation layer is thinned further and a positive hole tunnel current sufficient for erasing cannot be obtained unless the film thickness is reduced to at least 3.2 nm. Thus, more preferably, tox1 is set to 3.2 nm or less in order to pour positive holes into the electric charge accumulating layer 3 from the semiconductor region 1 using the direct tunnel phenomenon. From these relations, tox2 is desired to be more than (tox1+1.8 nm).

Further, it is permissible to form a metallic lining layer 6 on the gate electrode 5. The metallic lining layer 6 is composed of any one of WSi (tungsten silicide), NiSi, MoSi, TiSi, CoSi, W, and Al in the thickness of 10 to 500 nm. The metallic lining layer 6 constructs a gate wiring for connecting a plurality of the gate electrodes 5 under low resistance.

An insulation layer 7 composed of, for example, a silicon nitride film or silicon oxide film is formed on the metallic lining layer 6 in the thickness of 5 to 500 nm. Further, a side wall insulation film 8 composed of a silicon nitride film or silicon oxide film is formed on the side wall of the gate electrode 5 in the thickness of, for example, 2 to 200 nm. The side wall insulation film 8 and the insulation film 7 keep isolation between the gate electrode and source/drain region and between the gate electrode and contact/upper wiring layer.

If n-type impurity is, for example, ion-implanted into the p-type silicon semiconductor region 1 after the side wall insulation film 8 is formed, an n-type source region 9 and a drain region 10 are formed on both side faces of the gate electrode 5. Because the side wall insulation film 8 is formed at this time, damage due to ion-implantation at an end portion of the gate electrode 5 can be reduced. Since the contact and upper wiring layer to the source and drain regions are not main elements of the embodiment, representation thereof is omitted.

According to the embodiment, in order to prevent spreading of the threshold value due to deflection of electric field applied at the time of write-in and erasing, each of the thickness of the respective layers 2, 3, 4 constituting the gate insulation film is desired to be equal from a boundary between the semiconductor region 1 and the source region 9 to a boundary between the semiconductor region 1 and the drain region 10.

As shown in FIG. 1, a MONOS type EEPROM memory cell, in which the amount of electric charge accumulated in the electric charge accumulating layer 3 is handled as the amount of information, is formed of the source region 9, the drain region 10, the electric charge accumulating layer 3 and the gate electrode 5. A gate length is 0.01 μm or more and 0.5 μm or less. The source region 9 and the drain region 10 are formed by diffusion or ion-implantation of, for example, phosphor, arsenic or antimony in the depth of 10 to 500 nm so that the surface density thereof is 10¹⁷ (cm⁻³) to 10²¹ (cm⁻³).

FIG. 2 is a band diagram at the time of data erasing in the MONOS memory cell of the embodiment. This data erasing is carried out under the condition of implanting electrons from the gate electrode to the electric charge accumulating layer.

Reference numeral 11 in FIG. 2 shows schematically distribution of electric charges accumulated in the electric charge accumulating layer 3. This example indicates a case where the band is expanded downward considering a case where positive holes are accumulated in the electric charge accumulating layer 3. Of course, the accumulated electric charges does not have to be distributed in this shape and basically, only the moment position of electric charge is problematic in a following description.

FIG. 2 shows a case where the voltage of the gate electrode is 0 V when the source region and the drain region are kept floating in terms of potential by applying a voltage of 5 to 20 V to the p-type semiconductor region 1. Further, it is permissible to keep the voltage of the gate electrode at for example −5 to −20 V by applying 0 V to the source region, the drain region and the p-type semiconductor region 1. In this case, positive holes are implanted to the electric charge accumulating layer 3 from the p-type semi-conductor region 1 through the first insulation layer 2 according to the direct tunnel phenomenon. Here, if the moment position of the accumulated electric charge is approximated to an interface between the second insulation layer 4 and the electric charge accumulating layer 3 under the condition of implanting electrons from the gate electrode according to the FN tunnel phenomenon, it is found that even if the electric field Eox1 applied to the first insulation layer 2 is changed, as the erasing saturation threshold value, the electric field Eox2 applied to the second insulation layer 4 is substantially constant.

Here, an equation for introducing Eox1 and Eox2 from experimental data in erasing condition is indicated. First, where the gate voltage of the gate electrode with respect to the p-type semiconductor region 1 at the time of erasing is Vpp, the amount of electric charge accumulated in the nitride film of the electric charge accumulating layer 3 is QN and the capacity per unit area from the moment of the QN charge to the gate electrode 5 is C1, when surface band bending at the time of erasing is φs (the state of bending downward in FIG. 2 is regarded as positive) and the flat band voltage of the gate electrode when QN is 0 is VFBi, an equation (1) is established at the time of erasing.

Vpp=teff×Eox+VFBi+φs−QN/C1 (1)

Here, assume that QN is sufficiently larger than the absolute value of the amount of electric charges trapped by an interface level between the p-type semiconductor region 1 and the first insulation layer 2. A memory cell currently under trial production or on actual use can satisfy the aforementioned equation. The teff in the equation (1) is a valid film thickness obtained by converting the ONO film in the MONOS memory cell to a silicon oxide film and the equation (2) is established.

Teff=tox1/εox1+tN/EN+tox2/εox2 (2)

When a flat band voltage measured without band bending in the p-type semiconductor region 1 after erasing is assumed to be VFB, the Eox1 turns to 0 according to the Gausian principle. Thus, the following equation is established according to the equation (1).

QN=−C1×(VFB−VFBi) (3)

The Eox1 turns to an equation (4) according to the equations (1) and (3).

$$\begin{matrix}E o x1 = ( Vpp - VF B i - φ s - Q N / C1 ) / teff \\ = ( Vpp - VF B - φ s ) / teff\end{matrix} \qquad ( 4 )$$

Further, Eox2 is introduced in the form of the following equation according to the Gausian principle.

$$\begin{matrix}E o x2 = E o x1 - Q N / ( ϵ o x \cdot ϵ o x2 ) \\ = ( Vpp - VF B - φ s ) / teff + ( VFB - VFBi ) \times \\ C1 / ( ϵ o x \cdot ϵ o x2 )\end{matrix} \qquad ( 5 )$$

If the moment position of the QN is located on an interface between the second insulation layer and the electric charge accumulating layer when electrons are poured from the gate electrode to the electric charge accumulating layer at the time of erasing, approximation is established. The reason why such approximation is established is that as regards electricity conduction in the nitride film acting as an electric charge accumulating layer, a mobility of positive hole is three times or more than a mobility of electron. By measuring the moment of electric charge of a captured implanted electron in the MONOS memory cell, such a rational presumption that electrons are captured just very near the interface on the implantation side is introduced from experimental facts. In this case, assuming that the permittivity of the silicon oxide film is εox, C1 can be expressed as εox·εox2/tox2.

Further, the VFBi is a difference between Fermi energy of the semiconductor region 1 and Fermi energy of the gate electrode, and the difference between the p-type semiconductor region 1 and the n-type gate electrode is substantially −1 V while the difference between the p-type semiconductor region 1 and the p-type gate electrode is substantially 0 V. Accurately, they can be obtained by calculation on the impurity densities of the semiconductor region 1 and the gate electrode. Further, because electric field is applied to the p-type semiconductor region 1 to accumulate the electric charge, the surface band bending φs at the time of erasing may be considered substantially 0 V. Consequently, the Eox1 and Eox2 can be obtained experimentally according to the equations (3) and (5).

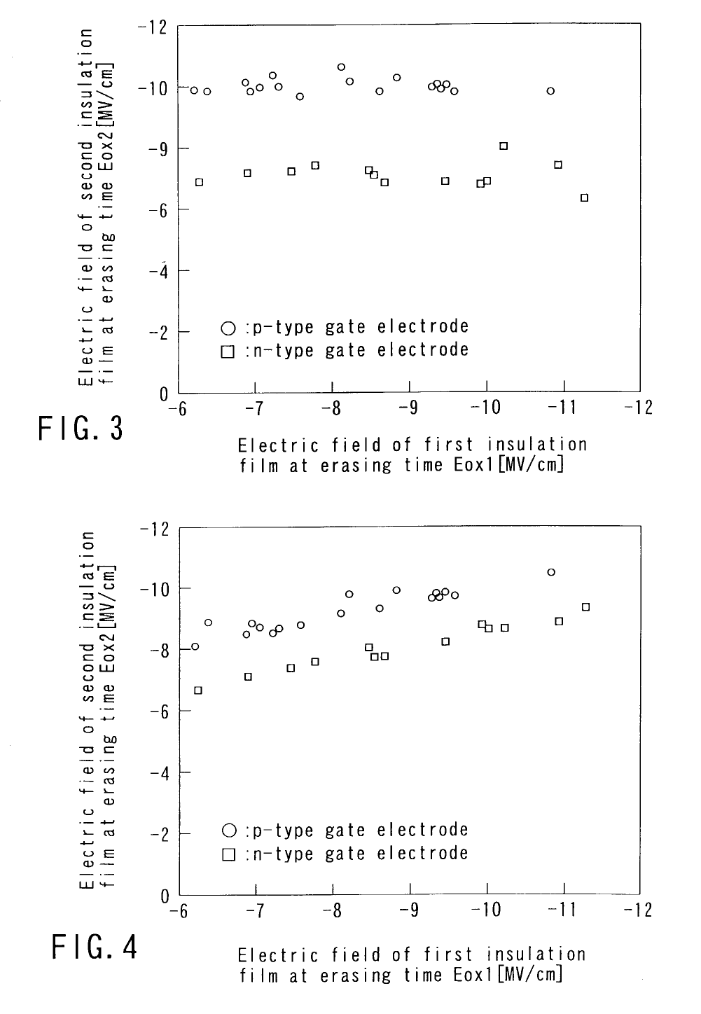

FIG. 3 indicates the values of Eox1 and Eox2 obtained according to the equations (3) and (5) from an erasing flat band voltage having an erasing pulse duration time of 1 second if with tox1 in the range of 2.0 nm or more and 3.5 nm or less in the MONOS memory cell shown in FIG. 1, tN is changed in the range of 6 to 20 nm, tox2 is changed in the term of 5 to 10 nm, and Vpp is changed in the range of −8 to −20 V. In this erasing condition, a value obtained above is compared with an erasing flat band voltage having the pulse duration time of 0.1 second and a value whose threshold value difference is within +0.2 V is selected as a value considered to be saturated.

A square symbol in FIG. 3 indicates a case of the n-type gate electrode to which phosphor is added in the range of 5×10¹⁹ (cm⁻³) or more and 10²⁰ (cm⁻³) or less and a round symbol in the same Figure indicates a case of the p-type gate electrode to which boron is added in the range of 1×10¹⁹ (cm⁻³) or more and 1×10²⁰ (cm⁻³) or less.

On the other hand, FIG. 4 shows the values of Eox1 and Eox2 obtained on an assumption that the electric charge moment is located on an interface between the first insulation layer 2 and the electric charge accumulating layer 3.

According to FIGS. 3 and 4, even if the moment position of the electric charge QN is located at any position in the nitride film and even if the Eox1 is changed in the range of −6 to −12 MV/cm, the Eox2 is changed only slightly. This is why while electron current flowing through the second insulation layer is Fowler-Nordheim (FN) tunnel current having a very strong dependency on electric field, while positive hole current flowing through the first insulation layer is direct tunnel current having a weaker dependency on electric field than the FN tunnel current. For example if hot hole current is supplied, the phenomenon that the Eox2 is changed only slight becomes more apparent because the hot hole current has a weaker dependency on the insulation film applied electric field than the tunnel current.

Further, as shown in FIG. 3, it has been found that when the erasing threshold value is saturated, Eox2 is hardly changed even if Eox1 is changed in a group having the same conductivity in the gate electrodes and that the p-type gate electrode and the n-type gate electrode can be approximated to substantially predetermined values of −10 MV/cm and −7 MV/cm respectively. After that, this predetermined value is set to Eox2p for the p-type gate electrode and Eox2n for the n-type gate electrode. Conversely, it means that a saturated erasing flat band value VFB can be obtained by using the aforementioned model with Eox2 constant. Actually, by modifying the equation (5), the erasing flat band voltage VFB can be obtained according to a following equation.

VFB=[εox·εox2(Vpp−φ−teff×Eox2)−teff×C1×VFBi]/(εox·εox2−teff×C1) (6)

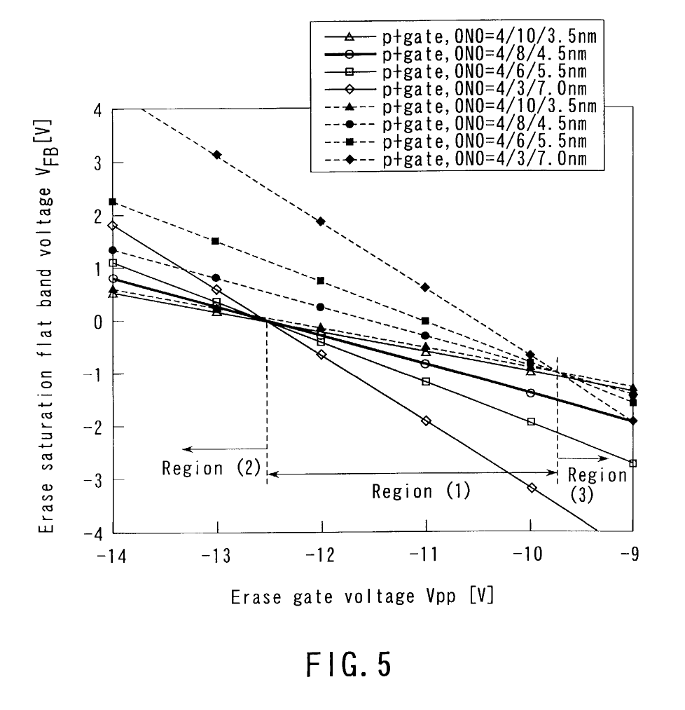

FIG. 5 shows values calculated according to the equation (6) on the VFB in case where the thickness of the first insulation layer is 4 nm, the thickness of the second insulation layer is x nm and the thickness of the electric charge accumulating layer is (17−2x) nm when the first insulation layer and the second insulation layer are formed of a silicon oxide film and the electric charge accumulating layer is formed of a silicon nitride film under the condition of εox1=εox2=εN/2. This condition specifies that the teff is constant while the gate drive characteristic and short channel effect from the gate electrode 5 to the semiconductor region 1 are constant. Assuming that the Vpp is constant under this condition, the erasing can be executed deeper as the VFB value is decreased.

This condition that with the thickness of the first insulation film constant, the sum of effective film thickness of the second insulation layer and the electric charge accumulating layer constant is the condition that application electric field is substantially the same at the time of write and the write speed is equal to erasing speed. Therefore, this can be said to be substantially the same condition for write and read.

In FIG. 5, its solid line indicates a case where the gate electrode is p-type and dotted line indicates a case where the gate electrode is n-type. Particularly, the case in which in the p-type gate electrode, the thickness of the second insulation layer is 4.5 nm and the thickness of the electric charge accumulating layer is 8 nm is indicated with a bold solid line according to an embodiment of the aforementioned U.S. Pat. No. 6,040,995. The embodiment of the U.S. Pat. No. 6,040,995 has disclosed a case where the Vpp is−14 V. In this case, as the thickness of the second insulation layer is increased, both the p-type gate electrode and the n-type gate electrode enter into a region in which the VFB rises (region (2) in FIG. 5). Even when the thickness of the second insulation layer is increased with teff kept constant, the VFB cannot be dropped.

On the other hand, it has been found that there exists a region (1) in FIG. 5 or a region in which in the p-type gate electrode, the VFB drops as the thickness of the second insulation layer is increased while in the n-type gate electrode, the VFB is raised as the thickness of the second insulation layer is increased. It has been further found that if the p-type gate electrode is utilized in this region, the VFB can be decreased effectively because the second insulation layer is thickened more by using the p-type gate electrode than the n-type gate electrode. Further, as a region in which the absolute value of the Vpp is low, there exists a region (3) in FIG. 5 or a region in which the VFB in both the p-type gate electrode and n-type gate electrode drops as the thickness of the second insulation layer is increased.

The region (1) is capable of increasing the absolute value of the Vpp as compared to this region (3) so as to achieve high-speed erasing and dropping the VFB effectively by only using the p-type gate electrode to thicken the second insulation layer. It has been found that this region is a new erasing voltage range region which the conventional n-type gate electrode is incapable of using.

According to the equation (6), the upper and lower limits of the region (1) are constant in teff and thus, a point where the VFB is not changed even if the tox2 is changed only should be obtained. When it is assumed that the VFBi of the p-type gate electrode is VFBip and the VFBi of the n-type gate electrode is VFBin, the range of the Vpp in the region (1) is as follows.

φs+teff×Eox2p+VFBip<Vpp<φs+teff×Eox2n+VFBin (7)

Here, the φs at the time of erasing in the p-type semiconductor region 1 is 0 V and if silicon is used for the p-type semiconductor region 1 and the gate electrode, the VFBip and VFBin may be 0 V and −1 V respectively. Thus, if the teff and Vpp are expressed in nm and volt respectively, the Vpp may be set up in a range specified by the following equation.

−1.0×teff<Vpp<−0.7×teff−1 (8)

Here, silicon nitride film formed using dichloro silane and ammonium usually has a permittivity twice silicon oxide film. Then, if the silicon oxide film is used for the first insulation layer and the second insulation layer, the range of the Vpp in the region (1) can be obtained according to the equations (2) and (8).

−1.0×(tox1+tN/2+tox2)<Vpp<−0.7×(tox1+tN/2+tox2)−1 (9)

The relation of currents flowing between the p-type semiconductor region 1 and the electric charge accumulating layer 3 has been described. Likewise, the erasing may be carried out by supplying positive hole current between the n-type source region 9 or the drain region 10 and the electric charge accumulating layer 3. In this case, it is rational to use a values of the flat portion on the source and drain regions supplied with positive hole current as tox1, tN and tox2.

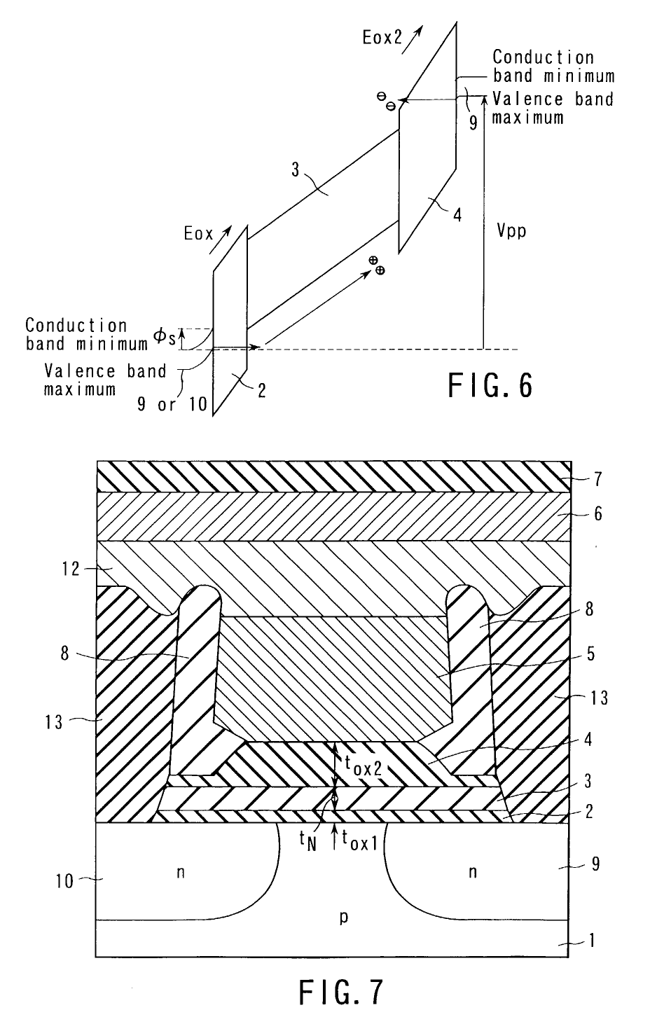

FIG. 6 shows a band diagram under the condition in which electrons are implanted into the electric charge accumulating layer from the gate electrode at the time of erasing of the embodiment. This diagram shows a case where a large potential difference is applied between the source/drain region and the gate electrode in the condition that a voltage of, for example, 5 to 20 V is applied to at least any one of the n-type source region 9 and the drain region 10, the voltage of the semiconductor region 1 is set from the voltage of the source/drain region to which voltage is applied to 0 V and the voltage of the gate electrode is −5 to −20 V.

Although the erasing may be carried out on the source side or the drain side or both the source and drain sides, the source and drain regions which voltage is applied to in order to implant positive holes into the electric charge accumulating layer are represented as source and drain regions. In this case, as positive holes are generated in the vicinity of an interface in contact with the first insulation layer 2 of the n-type source and drain regions 9, 10, band bending occurs so that a positive hole is implanted through the first insulation layer 2 according to the direct tunnel phenomenon.

In this case, the discussion which has introduced the above-described equations (1) to (9) is established by substituting the definitions of the φs, Vpp and VFB, VFBi. In FIG. 6, the surface band bending of the source region 9 or the drain region 10 at the time of erasing is replaced with φs, the voltage in the n-type source and drain regions 9, 10 is replaced with erasing gate voltage Vpp and electric field Eox applied to the first insulation layer and electric field Eox2 applied to the second insulation layer are indicated with each arrow. These signs are determined such that downward of this paper is positive. The VFBi is replaced with flat band voltage of the gate electrode with respect to the source region 9 or the drain region 10 when QN=0. After erasing, the flat band voltage obtained by measurement in the condition in which no band bending exists between the n-type source/drain regions 9, 10 and the first insulation layer is replaced with VFB.

In this way, the VFBi is a difference between Fermi energy of the source/drain regions 9, 10 and Fermi energy of the gate electrode 5. The n-type gate electrode relative to the n-type source/drain regions 9, 10 is positioned at substantially 0 V while the p-type gate electrode relative to the n-type source/drain regions 9, 10 is positioned at substantially 1 V. Accurately speaking, they can be obtained by calculating the impurity densities of the n-type source/drain regions 9, 10 and the gate electrode.

Because so much band bending occurs that positive holes are generated in the vicinity of an interface between the n-type source/drain regions 9, 10 and the first insulation layer at the time of erasing, it may be considered that the surface band bending φs is substantially inverted to the source/drain regions. In this case, the φs may be considered to be substantially −1 V. Consequently, it is found that such a region in which the VFB drops as the thickness of the second insulation layer is increased in the p-type gate electrode while the VFB rises as the thickness of the second insulation layer is increased in the n-type gate electrode can be acquired according to the evaluation equations (7), (8) and (9).

This analysis is established independently for the semiconductor region 1 and the n-type source/drain regions 9, 10. Thus, if positive holes are implanted into the electric charge accumulating layer 3 from the semiconductor region 1 when not the p-type semi-conductor region 1 but the n-type semiconductor region is used, the same discussion as when positive holes are implanted into the electric charge accumulating layer 3 from the n-type source/drain regions 9, 10 is established, so that the evaluation equations (7), (8) and (9) can be used.

In case where when the n-type semiconductor region is employed, the p-type source/drain regions are formed and then positive holes are implanted into the electric charge accumulating layer from the p-type source/drain regions, completely the same discussion as when positive holes are implanted into the electric charge accumulating layer from the p-type semiconductor layer is established so that the above-described evaluation equations (7), (8) and (9) can be used.

As described above, a new erasing voltage range specified by the evaluation equations (7), (8) and (9) is obtained in any memory cell composed of the n-type, p-type electric field effect transistors and apparently, the effect of the present invention is acquired.

In the MONOS memory cell of the first embodiment, the electric charge accumulating layer 3 can be erased equally when positive holes are implanted through direct tunnel from the semiconductor region 1 or the source/drain regions 9, 10 to the electric charge accumulating layer 3. Further, all positive hole current generated at that time can be used for tunnel implantation, so that implantation efficiency is high and power consumption at the time of erasing can be minimized.

From the principle introduced by the above-described equations (1) to (9), it is evident that dependency of the first insulation layer upon electric field when implanting positive holes from the semiconductor region 1 to the electric charge accumulating layer 3 occurs if electrons flowing from the gate electrode 5 to the electric charge accumulating layer 3 has weaker dependency than at the time of implantation of FN tunnel electrons. Thus, according to a modification in which positive hole implantation from the semiconductor region 1 into the electric charge accumulating layer 3 is carried out with hot holes, the height of the barrier wall of the first insulation layer 2 to the hot hole is by far smaller than that of the barrier wall in case where not-hot holes are employed. Therefore, dependency of the first insulation layer upon electric field is smaller than the direct tunnel. Thus, a new erasing voltage range is acquired in the range of the evaluation equation indicated in the equations (7), (8) and (9), so that apparently, the effect of the present invention can be obtained.

In case where hot holes generated between the source/drain regions 9, 10 and the p-type semiconductor region 1 are implanted into the electric charge accumulating layer 3 through the first insulation layer 2 under the same element structure as FIG. 1, a voltage of 5 to 20 V is applied to any one of the n-type source region 9 and the drain region 10, the voltage of the semiconductor region 1 is set to 0 V and the voltage of the gate electrode 5 is set to 0 to −15 V.

In this case, the Vpp in the equations (7), (8) and (9) only should adopt the voltage of the gate electrode based on the voltage of the semiconductor region 1. Further, when erasing is carried out by implantation of hot holes, tox1 does not always have to be smaller than 3.2 nm and tox2 does not have to be more than (tox1+1.8) nm.

According to the erasing method with the hot hole, the voltage to be applied to the source/drain regions and the gate electrode can be made smaller than that in the erasing method based on the direct tunnel, so that the erasing action can be achieved with a lower voltage.

The MONOS memory of the embodiment exerts following effects.

(1) When the erasing action is carried out by using the positive hole implantation from the semiconductor region into the electric charge accumulating layer in order to erase up to the same flat band voltage VFB, electron implantation from the gate electrode into the electric charge accumulating layer can be suppressed more than the conventional example in which a difference in film thickness between the second insulation layer and the first insulation layer is small. Thus, simultaneous implantation of positive hole and electron into the electric charge accumulating layer can be blocked. Increase in trap of the insulation film and the electric charge accumulating layer and increase in interface level can be reduced further so as to improve the reliability.

At the same time, by keeping constant the effective film thickness teff on the basis of conversion to the silicon oxide film of the ONO film and the first insulation layer thickness, write threshold value can be kept constant like the conventional example, thereby protecting write speed from dropping. Thus, a difference between the write threshold value and the erasing threshold value can be secured sufficiently, so that data reliability can be improved.

(2) When the same film thickness of the first insulation layer as the conventional example is used, the absolute value of the gate voltage at the time of erasing can be increased to achieve the same erasing threshold value as the conventional example, thereby reducing the erasing time. Because the film thickness of the first insulation layer is kept constant, the amount of electric charge leaking through the first insulation layer does not increase, so that holding characteristic of electrons can be kept the same as the conventional example. Because polycrystalline silicon layer containing p-type impurity is used for the gate electrode, less depletion of gate occurs at the time of write as compared to a case where the conventional polycrystalline silicon layer containing the n-type impurity is used, thereby achieving high-speed write at a low voltage.

(3) Because of a structure in which part of the electric charge accumulating film is removed from the source/drain regions, electric charge becomes unlikely to be accumulated in the removed region. Thus, a change in the amount of the electric charges accumulated, which is generated when the electric charge accumulating film is formed, for example, the processing step or the voltage in the source/drain region is changed, can be blocked so that resistance in the source/drain regions can be kept constant.

(4) The gate electrode can be disposed perpendicular to a direction in which the source region, the p-type semiconductor region (channel region) and the drain region are formed. Therefore, as described later, this is suitable for a structure in which the source region and the drain region of an adjacent memory cell are connected in series, for example, NAND type array structure.

As shown in a modification of the first embodiment of FIG. 7, the gate electrode 5 is formed and then a conductive layer 12 and the metallic lining layer 6 are formed thereon, so that a control line connected to the gate electrode 5 can be formed in the same direction as the direction in which the source region 9, the semiconductor region 1 (channel region) and the drain region 10. With such a structure, the AND array structure and Virtual Ground Array structure can be formed. Here, the conductive layer 12 is a polycrystalline silicon layer formed in the thickness of 10 to 500 nm as a result of doping, for example, boron of 1×10¹⁹ (cm⁻³) to 1×10²¹ (cm⁻³) and reference numeral 13 denotes an insulation film composed of a silicon oxide film or silicon nitride film. The insulation film 13 can be formed by burying between adjacent two gate electrodes after the source/drain regions 9, 10 are formed.

(Second Embodiment)

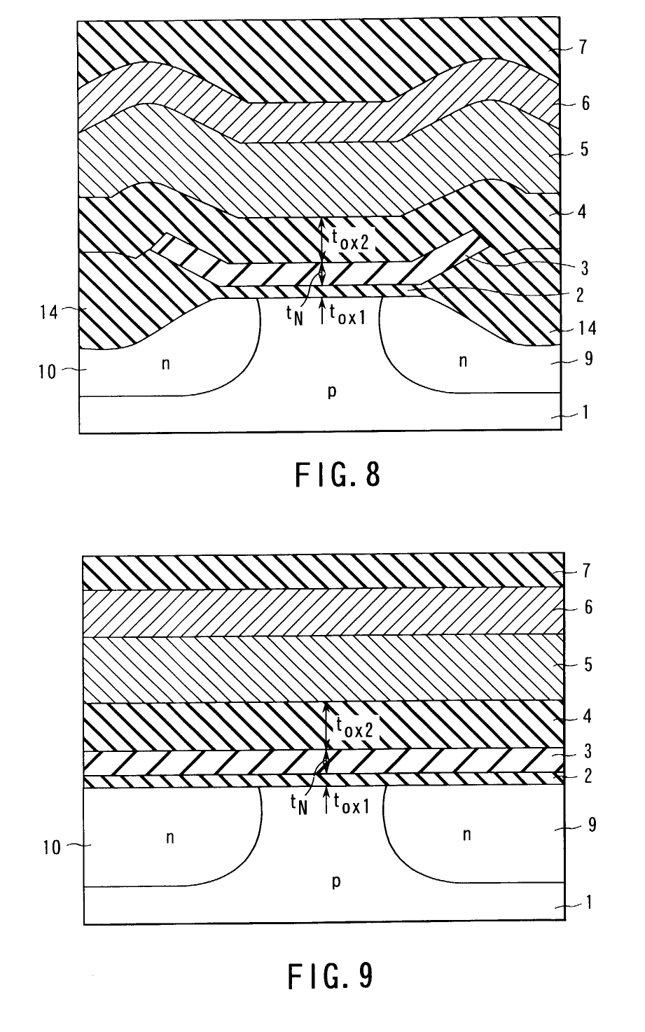

FIG. 8 is a sectional view showing the element structure of a MONOS memory cell according to a second embodiment of the present invention. In the MONOS memory cell of the embodiment, a control line composed of the metallic lining layer 6 connected to the gate electrode 5 of a polycrystalline silicon layer is formed such that it is extended from the MONOS memory cell of the first embodiment, in the same direction as the direction in which the source region 9, the semiconductor region 1 (channel region) and the drain region 10 are formed. Like reference numerals are attached to portions corresponding to FIG. 1 and a duplicated description thereof is omitted.

The MONOS memory cell of the embodiment is different from that shown in FIG. 1 in that an element isolating insulation film 14 composed of, for example, a silicon oxide film, is formed on the source/drain regions 9, 10 self aligningly.

This embodiment is different from the conventional example in that the thickness tox2 of the second insulation film 4 is more than 5 nm and that the gate electrode 5 is composed of a p-type semiconductor.

Referring to FIG. 8, the first insulation layer 2 composed of a silicon oxide film or oxynitride film having a thickness of 0.5 to 10 nm is formed on the p-type semiconductor region 1 containing impurity such as boron or indium in the density of 10¹⁴ (cm⁻³) to 10¹⁹ (cm⁻³). Here, assume that the thickness of the flat portion of the first insulation layer 2 is tox1 and the relative permittivity to the silicon oxide film is εox1.

The first insulation layer 2 is processed into stripes, for example, and the element isolating insulation film 14 composed of, for example, a silicon oxide film is formed on both sides in the thickness of 0.05 to 0.5 μm. The electric charge accumulating layer 3 composed of, for example, a silicon nitride film is formed partly on each of the first insulation layer 2 and the element isolating insulation film 14. Assume that the thickness of the flat portion on the first insulation layer of the electric charge accumulating layer 3 is tN and the relative permittivity to the silicon oxide film is εN.

Such a configuration can be acquired by oxidizing the semiconductor region 1 with oxidizing environment after the first insulation layer 2 is entirely formed on the semiconductor region 1, the electric charge accumulating layer 3 is entirely deposited and the electric charge accumulating layer 3 is patterned.

The source region 9 and the drain region 10 are formed by diffusion or ion implantation of phosphor, arsenic or antimony in the depth of 10 to 500 nm in the semiconductor region 1 below the element isolating insulation film 14 so that the surface density thereof is 10¹⁷ (cm⁻³) to 10²¹ (cm⁻³). The source region 9 and the drain region 10 can be formed by self-aligning with the element isolating insulation film 14 by using the patterned electric charge accumulating layer 3 as a mask.

The gate electrode 5 composed of a polycrystalline silicon layer which for boron is doped as impurity in the range of 1×10¹⁹ (cm⁻³) to 1×10²¹ (cm⁻³) through the block insulation film (second insulation film) 4 composed of a silicon oxide film or oxynitride film is formed in the thickness of more than 5 nm and 30 nm or less. Here, keeping the density of boron in the gate electrode 5 in the range of 1×10²⁰ (cm⁻³) or less is preferable for preventing abnormal diffusion of boron in the silicon oxide film and stabilizing the threshold value of the p-type MOS field transistor formed at the same time. If the density of boron in the gate electrode 5 is kept to 1×10¹⁹ (cm⁻³) or more, electric field applied to the ONO film is decreased due to depletion of the gate electrode, which is preferable for preventing increase of the erasing time.

Here assume that the thickness of the flat portion of the second insulation layer 4 is tox2 and the relative permittivity to the silicon oxide film is εox2.

The feature of the MONOS memory cell of the second embodiment with respect to the conventional example is that its gate electrode 5 is of p-type and the thickness tox2 of the second insulation layer 4 is more than 5 nm. Preferably, current which tunnels the second insulation layer 4 at the time of erasing is reduced in order to prevent saturation of the erasing threshold value. Assuming that the tox2 is more than 5 nm, when electric field is applied to the second insulation layer 4 at the time of erasing, not direct tunnel current but Fowler Nordheim (FN) current flows thereby making it possible to keep small current flowing through the second insulation layer 4.

When the silicon oxide film or silicon oxynitride is employed for the first insulation layer 2, no tunnel phenomenon occurs unless the height of barrier to positive holes is higher by 1 eV or more than that of barrier to electrons. No sufficient tunnel current can be secured until the thickness thereof is reduced to at least 3.2 nm or less. Thus, preferably, the tox1 is set to 3.2 nm or less in order to implant positive holes into the electric charge accumulating layer 3 from the semiconductor region 1 using direct tunnel phenomenon. Thus, preferably, the tox2 is more than (tox1+1.8) nm. It is permissible to use a deposited silicon oxide film such as TEOS, HTO for the second insulation layer 4 or a silicon oxide film or silicon oxynitride obtained by oxidizing the electric charge accumulating layer 3.

Further, it is permissible to form the metallic lining layer 6 of at least one of, for example, tungsten silicide (WSi), MoSi, TiSi, CoSi, W and Al on the gate electrode 5 in the thickness of 10 to 500 nm. The metallic lining layer 6 constructs gate wiring for connecting a plurality of the gate electrodes 5 under a low resistance.

Further, the insulation layer 7 composed of a silicon nitride film or silicon oxide film is formed on the metallic lining layer 6 in the thickness of 5 to 500 nm.

In the second embodiment also, preferably, the first insulation layer 2, the electric charge accumulating layer 3 and the second insulation layer 4, which construct the ONO film, are equalized in terms of thickness from a boundary between the semiconductor region 1 and the source region 9 to a boundary between the semiconductor region 1 and the drain region 10, in order to prevent spreading of the threshold value due to deflection of electric field at the time of write or erasing.

Further, the n-type source and drain regions 9, 10 are formed across a region in which the p-type semiconductor region 1 and the first insulation film 2 contact each other. The MONOS type EEPROM memory cell which handles the amount of electric charges accumulated in the electric charge accumulating layer 3 as the amount of information is formed of the source and drain regions 9, 10, the electric charge accumulating layer 3 and the gate electrode 5. Then, an interval between the source region 9 and the drain region 10, that is, the channel length shall be 0.01 or more and 0.5 μm or less.

The MONOS memory cell of the second embodiment has following effects as well as the effects (1), (2) and (3) like the first embodiment shown in FIG. 1.

(4) The gate electrode 5 is formed in extension in the same direction as the direction in which the source region 9, the semiconductor region 1 (channel region) and the drain region 10 are formed. Therefore, as described above, this is suitable for the structure for connecting the source region and drain region in adjacent memory cells in parallel, for example, achieving the AND type array structure or Virtual Ground Array structure. Because the element isolating insulation film 14, the source and drain regions 9, 10 and the electric charge accumulating layer 3 can be formed self aligningly, it is not necessary to secure an allowance for deflection between those layers, so that a higher density memory cell is achieved.

(Modification of the Second Embodiment)

FIG. 9 shows the element sectional structure of a MONOS memory cell according to a modification of the second embodiment. Although the element structure of the modification is basically the same as the second embodiment, it differs from the second embodiment in that the element isolating insulation film 14 is not formed, so that element isolation is not achieved.

The MONOS memory cell of the modification is formed by for example, forming the source/drain regions 9, 10 in the p-type semiconductor region 1 by ion implantation, forming the gate insulation film comprises the first insulation layer 2, the electric charge accumulating layer 3 and the second insulation layer 4 on the semiconductor region 1, depositing polycrystalline silicon layer and metallic lining layer 6 entirely so as to form the gate electrode 5 and then, patterning the gate insulation film, polycrystalline silicon layer and metallic lining layer 6. Because the film thickness condition of each layer and film may be the same as that described in the second embodiment, description thereof is omitted.

The modification can gain following effects as well the effects (1) and (2) of the first and second embodiments.

(5) The gate electrode 5 is formed in extension in the same direction as the direction in which the source region 9, the semiconductor region 1 (channel region) and the drain region 10 are formed. Therefore, as described above, this is suitable for the structure for connecting the source region and drain region in adjacent memory cells in parallel, for example, achieving the AND type array structure or Virtual Ground Array structure. Further, because no element isolating insulation film is formed in the direction in which the semiconductor region 1 and the drain region 10 are formed, the thickness of each of the first insulation layer 2, the electric charge accumulating layer 3 and the second insulation layer 4 is never changed at a element isolating insulation film formation end, so that a memory cell having more uniform thickness can be achieved. Thus, distribution of the write and erasing threshold values can be made smaller.

The MONOS memory cells according to the second embodiment and its modification are capable of achieving erasing action with the same voltage related structure as the first embodiment and apparently, the same effect as the first embodiment is present.

(Third Embodiment)

The first and second embodiments have handled the MONOS memory cells capable of erasing quickly by using the p-type semiconductor electrode (polycrystalline silicon layer containing p-type impurity) as the gate electrode of the memory cell.

In the third embodiment, a semiconductor memory device, in which a plurality of surface channel type peripheral transistors comprises n-type MISFET and p-type MISFET is formed in the same substrate thereof together with the MONOS memory cell using the p-type semiconductor electrode described in the first and second embodiments, will be described.

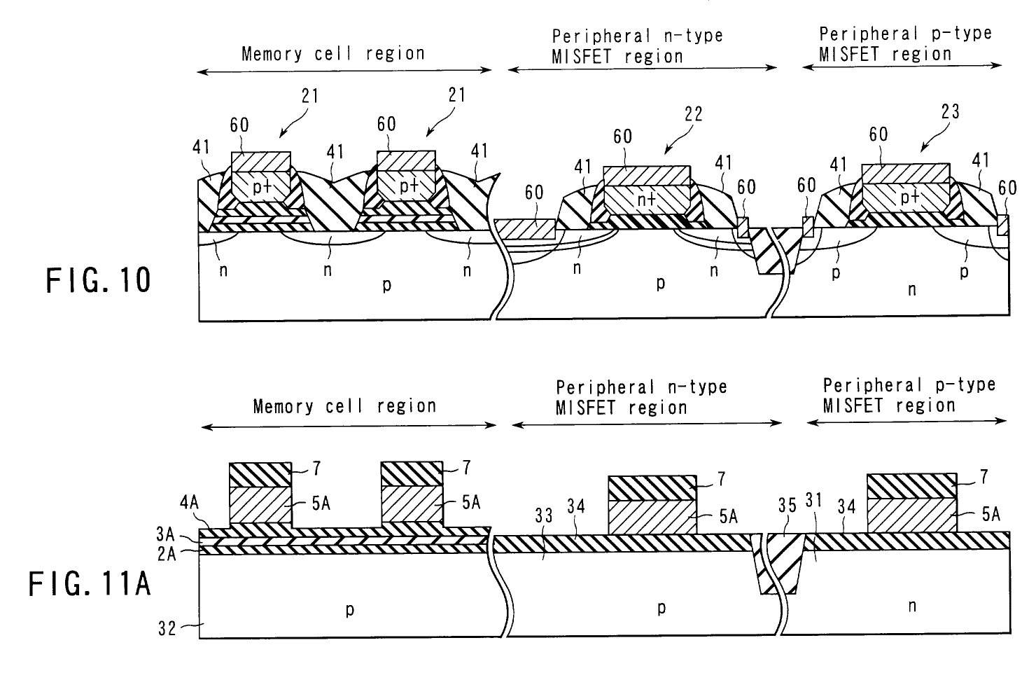

FIG. 10 shows an element sectional structure of the semiconductor memory device according to the third embodiment. In FIG. 10, like reference numerals are attached to portions corresponding to the firs and second embodiments and detailed description thereof is omitted.

In the semiconductor memory device shown in FIG. 10, a plurality of memory cells 21 composed of the p-type gate MONOS having shallow n-type source and drain regions, a surface channel n-type MISFET 22 having the n-type gate containing deeper source and drain regions, and surface channel p-type MISFET 23 having the p-type gate containing source and drain regions deeper than the memory cell region are integrated in the same substrate. This example indicates a case where two memory cells 21 are formed adjacent each other. This is on assumption of a memory having the NAND type array structure in which plural memory cells are connected in series and the number of the memory cells 21 is not restricted to two but may be plural. Reference numeral 60 denotes salicide formed on each gate electrode and source/drain regions.

As described in the first and second embodiments, each of plural memory cells 21 shown in FIG. 10 is constituted of a semiconductor in which the thickness of the second insulation is more than 5 nm and the gate electrode contains p-type impurity.

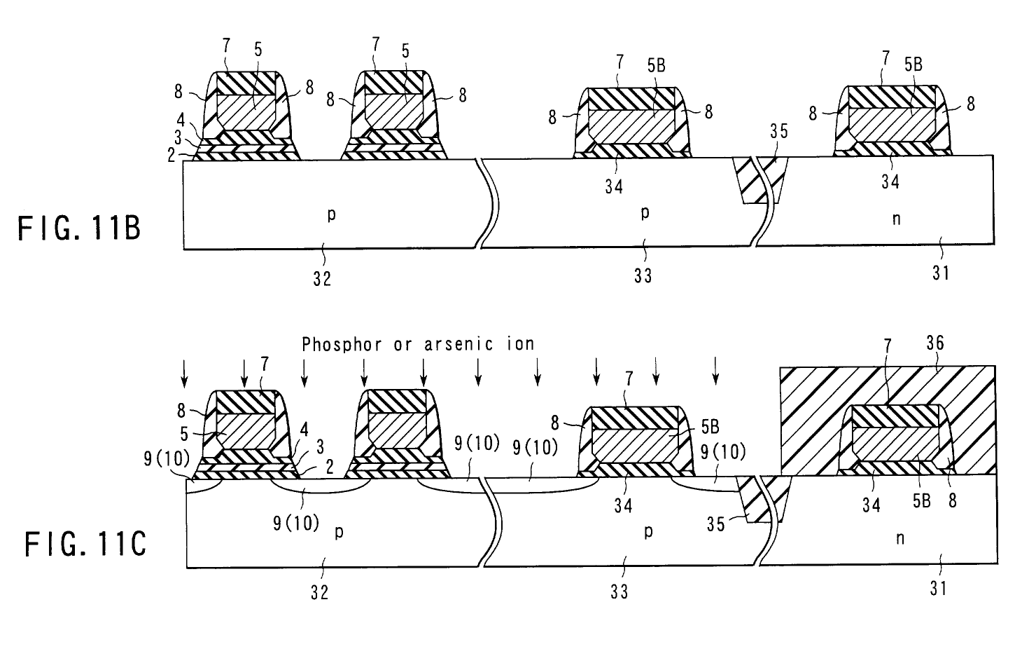

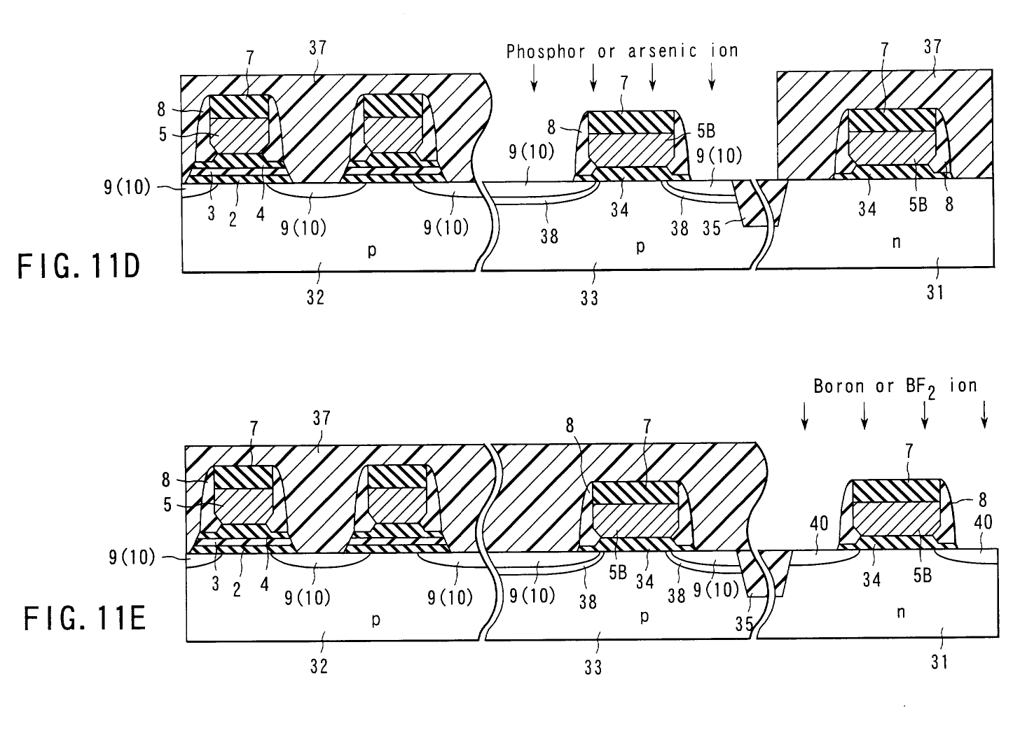

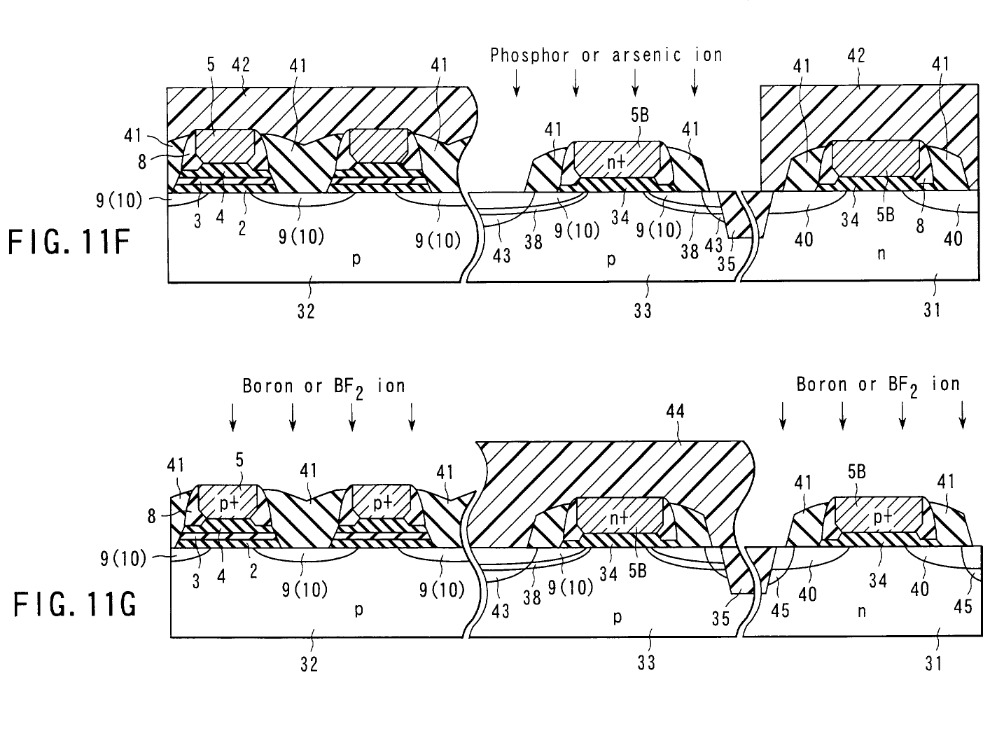

Next, a method of manufacturing the semiconductor memory device shown in FIG. 10 will be described with reference to FIGS. 11A to 11G.

As shown in FIG. 11A, a p-type silicon substrate (not shown) containing boron in the density of 10¹⁴ (cm⁻³) to 10¹⁹ (cm⁻³) as impurity is coated with resist so as to execute lithography. Ions of, for example, phosphor, arsenic, or antimony is implanted in the dose amount of 1×10¹¹ to 1×10¹⁵(cm⁻²) at the acceleration energy of, for example, 30 to 1,000 KeV so as to form an n-type well 31 in the peripheral p-type MISFET region. Likewise, ions of boron or indium, for example, boron is implanted into the p-type silicon substrate in the dose amount of 1×10¹¹ to 1×10¹⁵(cm⁻²) at the acceleration energy of 100 to 1,000 KeV so as to form a p-type well 32 in the memory cell region and a p-type well 33 in the peripheral n-type MISFET region. The p-type well 32 formed in the memory cell region corresponds to the p-type semiconductor region 1 of the first and second embodiments.

After coating with resist, lithography is carried out and channel ions are implanted into the memory cell region and the peripheral n-type MISFET region. In this case, if boron is used as the impurity, it is implanted at the acceleration energy of 3 to 50 KeV and if indium is used, it is implanted at the acceleration energy of 30 to 300 KeV in the dose amount of 1×10¹¹ to 1×10¹⁴ (cm⁻²) After that, for example, lithography is carried out and phosphor or arsenic may be implanted in the dose amount of 1×10¹¹ to 1×10¹⁴(cm⁻²) at the acceleration energy of 3 to 50 KeV so as to set up the threshold value of transistors to be formed in the peripheral p-type MISFET region.

Subsequently, a silicon oxide film or oxynitride film 2A, which becomes a tunnel insulation film in the memory cell transistor, is formed entirely on the p-type well 32 in the thickness of 0.5 to 10 nm. After that, a silicon nitride film 3A is formed in the thickness of 3 to 50 nm. Further, a silicon oxide film or oxynitride film 4A is deposited thereon in the thickness of more than 5 nm to 30 nm or less.

Further, the memory cell region is covered with resist and selectively removed so that the silicon oxide film or oxynitride film 2A, the silicon nitride film 3A and the silicon oxide film or oxynitride film 4A are left on the memory cell region. After that, a silicon oxide film or oxynitride film 34, which becomes the gate insulation film of the peripheral transistors, is formed in the thickness of 0.5 to 20 nm. After this process, an element isolation region 35 composed of a silicon oxide film is formed in the peripheral n-type MISFET region and the peripheral p-type MISFET region. The depth of the element isolation region 35 is for example, 0.05 to 0.5 μm.

Further, for example, amorphous silicon film or polycrystalline silicon film 5A is deposited entirely in the thickness of 10 to 500 nm. Preferably, the polycrystalline silicon film 5A is a film containing no n-type or p-type impurity intentionally and after that, the p-type and n-type gate electrodes are formed by doping the n-type and p-type impurity. Next, a silicon oxide film or nitride film 7, which serves as a mask material, is deposited entirely in the thickness of 10 to 500 nm. After that, lithography and anisotropic etching are executed so as to process the polycrystalline silicon film 5A vertically and the etching is stopped with the silicon oxide film or oxynitride film 34 and the silicon oxide film or oxynitride film 4A, thereby the configuration shown in FIG. 11A is acquired.

At this time, stopping etching for gate side wall processing at the silicon oxide film or oxynitride film 4A is preferable for reduction of processing damage to the silicon nitride film 3A, which serves as an electric charge accumulating layer. Particularly, the structure in which the thickness of the second insulation film (silicon oxide film or oxynitride film 4A) constituting the gate insulation film of the memory cell is more than 5 nm can stop etching more easily than the conventional example.

After that, for example, a silicon oxide film having a thickness of 2 to 300 nm is formed as the side wall insulation film 8 by annealing in oxidizing environment so as to reduce defect in the surface of the semiconductor substrate. It is permissible to deposit a silicon oxide film or silicon nitride film composed of, for example, TEOS or HTO, as the side wall insulation film 8 in this oxidizing step. After that, with the side wall insulation film 8 as a mask, the silicon oxide film or oxynitride film 2A, the silicon nitride film 3A and the silicon oxide film or oxynitride film 4A are removed selectively so as to form the first insulation layer 2, the electric charge accumulating layer 3 and the first insulation layer 4 in the memory cell transistor. Consequently, the structure shown in FIG. 11B is formed.

A gate electrode 5B of the peripheral transistor is formed with the amorphous silicon film or polycrystalline silicon film 5A in the peripheral n-type MISFET region and the peripheral p-type MISFET region.

Further, resist 36 is applied and lithography and patterning are carried out to at least cover the peripheral p-type MISFET region. After that, phosphor ion or arsenic ion is implanted in the dose amount of 1×10¹³ to 5×10¹⁴(cm⁻²) at the acceleration energy of 1 eV to 50 KeV so as to form the n-type source/drain region 9 (and 10) in the memory cell region and the peripheral n-type MISFET region. In this case, if the number of ions implanted is set smaller than the number of ions implanted for forming the p-type source and drain regions, which will be described later, this process of coating with resist is not required and ions may be implanted into the entire face. In this case, preferably, the acceleration energy and dose amount are set smaller than a case for forming the n-type source and drain regions to be formed later, in order to make shallow bonding and diffusion in the memory cell thereby blocking short channel effect. Consequently, the structure shown in FIG. 11C is formed.

It is permissible to form a so-called LDD structure or extension region by coating with resist 37, patterning by lithography so as to cover the memory cell region and the peripheral p-type MISFET region and implanting phosphor ion or arsenic ion into the p-type well 33 in the peripheral n-type MISFET region so as to form n-type source and drain regions 38 deeper than the n-type source/drain region 9 (and 10) in the peripheral n-type MISFET region. After that, phosphor ion or arsenic ion is implanted in the dose amount of 2×10¹³ to 1×10¹⁵(cm⁻²) at the acceleration energy of 5 eV to 50 KeV so as to form the n-type source/drain regions 38. Preferably, the dose amount for forming the source and drain regions 38 is set larger than the case for forming the source/drain region 9 (and 10). Consequently, source/drain resistance in the peripheral transistor is dropped so that current driving performance is increased. Preferably, that dose amount is set smaller than in n-type source/drain regions 43, which will be described later, in order to block the short channel effect of the peripheral transistor. Consequently, the configuration shown in FIG. 11D is obtained.

Further, it is permissible to create a so-called LDD or extension region by coating with resist 39 and patterning by lithography so as to cover the memory cell region and n-type MISFET region. After that, boron or BF₂ ions are implanted in the dose amount of 2×10¹³ to 1×10¹⁵(cm⁻²) at the acceleration energy of 5 eV to 50 KeV so as to form p-type source and drain regions 40. Preferably, the dose amount at this moment is set smaller than the case for forming p-type source and drain regions 45, which will be described later, in order to block the short channel effect of the peripheral transistor. Consequently, the configuration shown in FIG. 11E is acquired.

After that, for example, a silicon oxide film or silicon nitride film is deposited in the thickness half or more an interval of the side wall insulation film of an adjacent memory cell, for example, the thickness of 30 to 200 nm and then, anisotropic etching is carried out to form the side wall insulation film 41. The insulation film 41 is left between memory cells such that it reaches the height of the gate electrode 5 and functions as protecting film for blocking impurity ions from being implanted when implanting ions into the peripheral transistor. Additionally, it acts as a side wall which blocks the source and drain regions 43, 45 deeper than the LDD or extension portion which are shallow source and drain regions, which will be described later, from approaching the gate electrode 5. After the step of forming the side wall insulation film 41, the insulation film 7 formed on the gate electrode 5 is removed.

Further, resist 42 is applied and patterning is carried out by lithography so as to cover the memory cell region and p-type MISFET region. After this, phosphor or arsenic ions are implanted in the dose amount of 1×10¹⁴(cm⁻²) to 1×10¹⁶(cm⁻²) at the acceleration energy of 1 eV to 50 KeV so as to form the n-type source and drain regions 43. An n-type electrode can be acquired by doping n-type impurity to the gate electrode 5B in the n-type MISFET region. Consequently, the configuration shown in FIG. 11F is obtained.

Additionally, resist 44 is applied and patterning is carried out by lithography so as to cover the n-type MISFET region. After this, boron or BF₂ ions are implanted in the dose amount of 1×10¹⁴(cm⁻²) to 1×10¹⁶(cm⁻²) at the acceleration energy of 1 eV to 50 KeV so as to form the p-type source and drain regions 45. At this moment, acceleration energy is selected for implanted ions not to reach the p-type well 32 in the memory cell region. In the ion implanting step, the p-type gate electrode may be formed by doping p-type impurity to the gate electrode 5B in the memory cell region and the p-type MISFET region. Consequently, the configuration shown in FIG. 11G is obtained. The phenomenon that boron added to the gate electrode SB oozes to the n-type well 31 is restricted more if boron is used as implanted ion than when BF₂ is employed.

After metal for creating silicide such as Ti, Co, Ni, or Pd is deposited in the entire range of 1 to 40 nm, heating step of 400 to 1,000° C. is added so as to form silicide. After that, remaining metals are removed by etching with sulfuric acid and peroxide solution so as to form silicide 60 as shown in FIG. 10.

The third embodiment ensures following effects as well as the effect of the first embodiment.

(6) The MONOS memory cell of the p-type electrode having a shallow n-type source and drain regions, the n-type MISFET having the n-type gate electrode containing deeper source and drain regions and the p-type MISFET having p-type gate electrode are integrated in the same substrate. Thus, the surface channel p-type MISFET and n-type MISFET can be formed with the memory cell at the same time, so that a transistor having excellent short channel effect, high current driving performance and lower threshold value can be produced. As a result, the p-type MISFET occupied area can be reduced and a memory cell and peripheral circuit capable of operating even if power supply voltage is dropped can be achieved.

(7) The diffusion depth of the source and drain regions in the n-type MISFET having an n-type gate electrode and the p-type MISFET having a p-type gate electrode can be controlled so as to be deeper than the diffusion depth of the source and drain regions in the MONOS memory cell independently, so that layer resistance of the source and drain regions is reduced while the short channel effect of the memory cell can be restricted.

(8) The gate electrodes of the peripheral transistor and the memory cell can be processed in the same process. Thus, no deflection occurs in forming the gates of the peripheral transistor and memory cell, thereby achieving a higher density memory cell. Because ion implantations to the gate electrode of the p-type gate MONOS memory having shallow n-type source and drain regions and the gate electrode of the p-type MISFET having the p-type gate electrode are carried out in the same process, increase of the number of steps can be suppressed as compared to another process. Further, because the density of the p-type impurity of the gate electrode is set to 2×10¹⁹ (cm⁻³) or more and less than 1×10²⁰ (cm⁻³), the p-type impurity added to the gate of the p-type MISFET having the p-type gate is never diffused abnormally in the silicon oxide film and keeps the quality of the silicon oxide film, thereby preventing the p-type impurity from oozing to the well region in which the MOSFET is formed. Thus, increase in the deflection of the threshold value of the p-type MISFET can be blocked depending on the oozing amount of the p-type impurity.

(9) Because ion implantations to the deep source and drain regions and the gate electrode in the peripheral transistor are carried out in the same process, increase of the number of processing steps can be blocked as compared to another process.

(10) Because the insulation film 41 is formed on the MONOS memory cell as shown in FIG. 10, penetration of the p-type impurity into the source and drain regions of the memory cell can be blocked in a process of adding the p-type impurity into the gate electrode of the memory cell. Thus, thin n-type source and drain regions and a gate electrode having high p-type impurity density necessary for blocking depletion of the gate can be realized, so that a memory cell having an excellent short channel effect and a large current driving ability can be achieved. Further, because no silicide is formed on the shallow source and drain regions when silicide is created selectively on the gate electrode of the MONOS memory cell, gate resistance is decreased and generation of leak current originating from silicide in the shallow source and drain regions can be blocked.

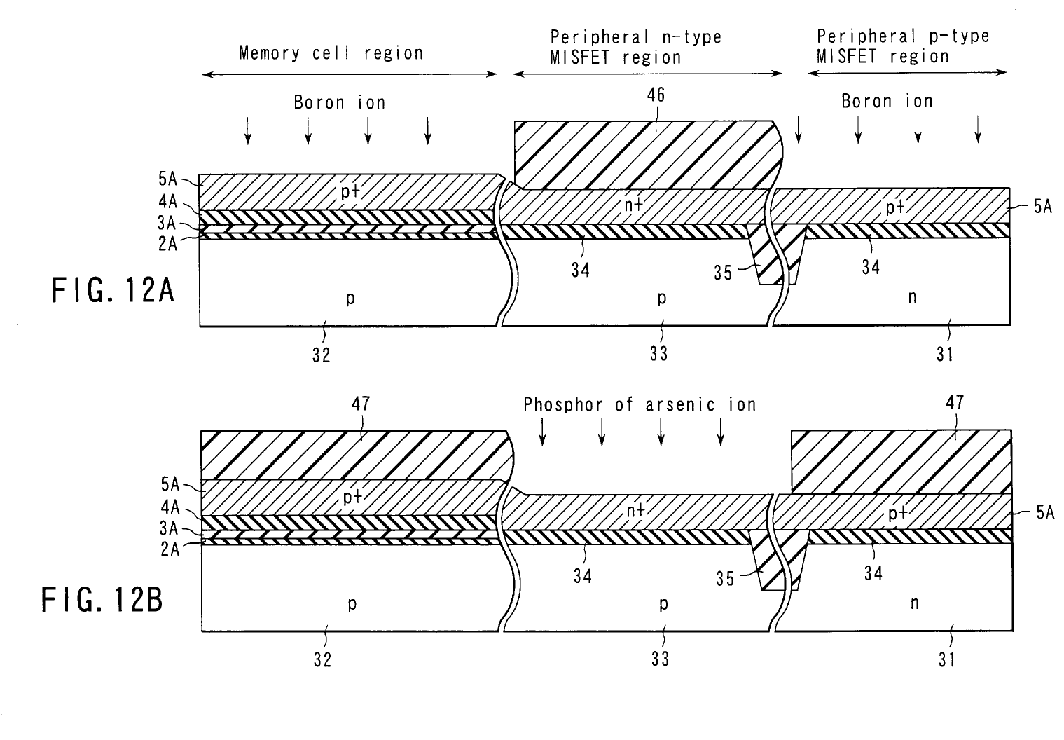

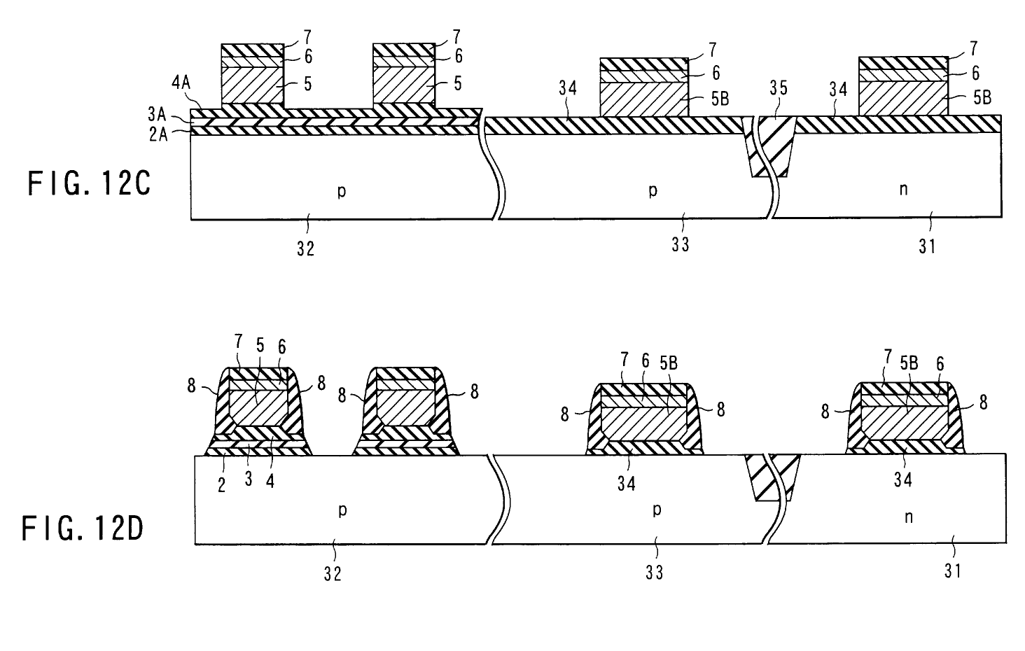

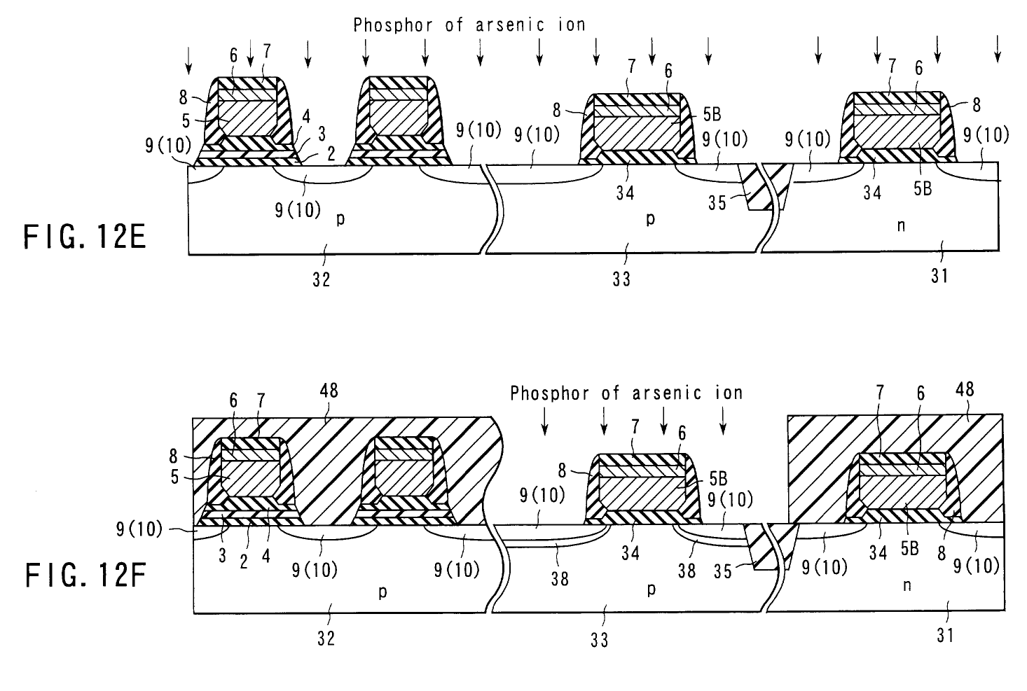

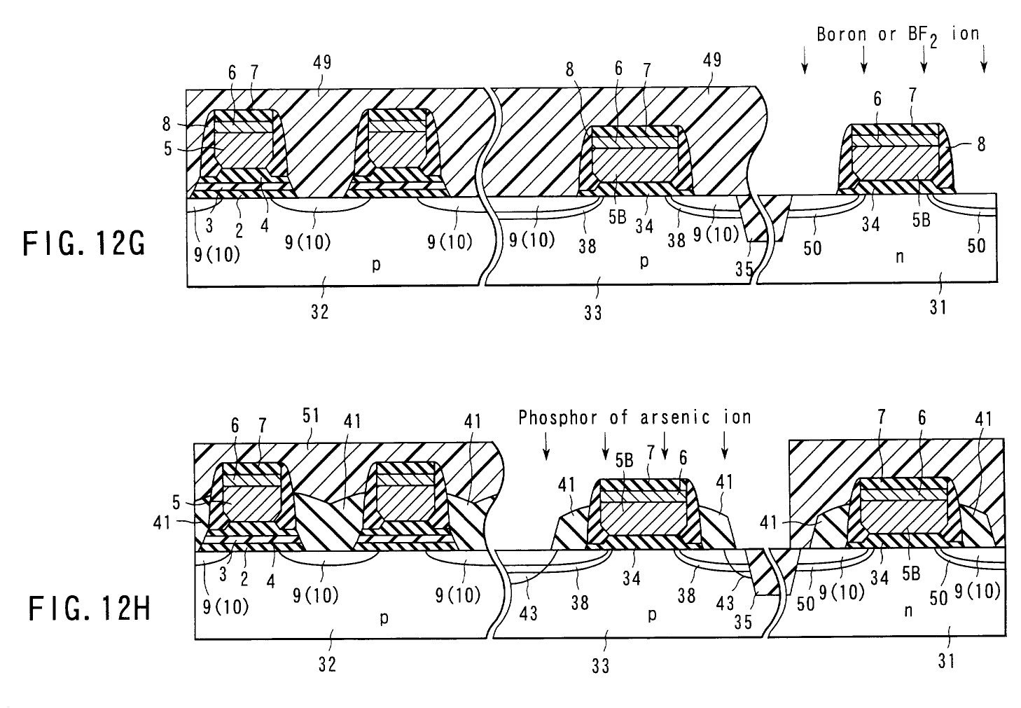

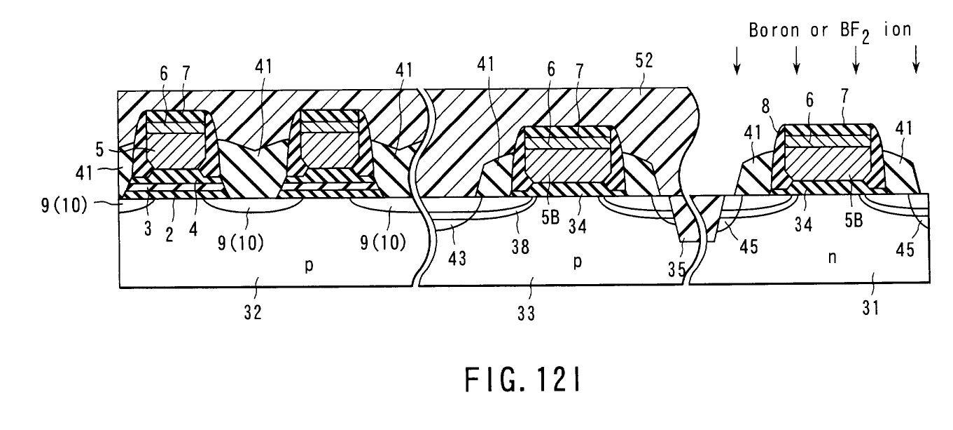

In addition, silicide can be formed on the deep source and drain regions of the peripheral transistor, thereby a low resistance source and drain regions causing little leak current can be formed. (Modification of the third embodiment) A modification of the third embodiment will be described with reference to FIGS. 12A to 12I. The modification is different from the third embodiment in that impurity is doped to the gate electrode before the source and drain regions are formed.

The process for depositing amorphous silicon film or polycrystalline silicon film 5A on the entire surface in the thickness of 10 to 500 nm is the same as the third embodiment. Preferably, the silicon film 5A is a film containing no n-type or p-type impurity intentionally and after that, the p-type and n-type gate electrodes are formed by doping the n-type and p-type impurities.

After that, resist 46 is applied and patterning is carried out by lithography so as to cover the n-type MISFET region. After that, boron ions or BF₂ ions are implanted in the dose amount of 1×10¹⁴(cm⁻²) to 1×10¹⁶(cm⁻²) at the acceleration energy of 1 eV to 50 KeV so as to dope p-type impurity to the gate electrode of the memory cell having the silicon film 5A and the gate electrode of the p-type MISFET. Boron ion is more preferable than BF₂ ion to prevent the impurity ion from passing through the gate insulation film 34. At this moment, the acceleration energy is adjusted so that no ion passes through the overlaid structure comprised of the silicon oxide film or oxynitride film 2A, the silicon nitride film 3A and the silicon oxide film or oxynitride film 4A and then no p-type impurity reaches the p-type well 32. Consequently, the configuration shown in FIG. 12A is acquired.

Further, resist 47 is applied and then, patterning is carried out by lithography so as to cover the memory cell region and the p-type MISFET region. Phosphor or arsenic ions are implanted in the dose amount of 1×10¹⁴(cm⁻²) to 1×10¹⁶(cm⁻²) at the acceleration energy of 1 eV to 50 KeV so as to dope n-type impurity to the gate electrode of the n-type MISFET of the silicon film 5A. Consequently, the configuration shown in FIG. 12B is obtained.

Subsequently, a metallic film, which serves as the metallic lining layer 6 of the gate electrode composed of, for example, NiSi, MoSi, TiSi, CoSi, W, or Al is deposited in the thickness of 10 to 500 nm. Further, a silicon oxide film or nitride film 7, which acts as mask material, is deposited on the entire surface in the thickness of 10 to 500 nm. After that, the silicon film 5A is processed vertically by lithography and anisotropic etching and the etching is stopped by the silicon oxide film 34 and silicon oxide film or oxynitride film 4A so as to acquire the configuration shown in FIG. 12C. Preferably, processing damage to the silicon nitride film 3A which acts as an electric charge accumulating layer is minimized by stopping etching for gate side wall processing with the silicon oxide film or oxynitride film 4A. Particularly, such a structure in which the thickness tox2 of the silicon oxide film or oxynitride film 4A is more than 5 nm, is capable of stopping etching more easily than the conventional example.

Further, for example, a silicon oxide film having a thickness of 2 to 300 nm is formed as the side wall insulation film 8 by annealing in oxidizing environment in order to reduce surface defect in the semiconductor substrate. It is permissible to deposit silicon oxide film or silicon nitride film composed of TEOS or HTO as the side wall insulation film 8 in this oxidizing step. After that, with the side wall insulation film 8 as a mask, the silicon oxide film or oxynitride film 2A, the silicon nitride film 3A and the silicon oxide film or oxynitride film 4A are removed selectively so as to form the first insulation layer 2, the electric charge accumulating layer 3 and the second insulation layer 4. Consequently, the structure shown in FIG. 12D is formed.

Further, phosphor ions or arsenic ions are implanted in the dose amount of 1×10¹³(cm⁻²) to 1×10¹⁴(cm⁻²) at the acceleration energy of 1 eV to 50 KeV so as to form n-type source and drain regions 9, 10. Here, the amount of ion implantation is set smaller than the amount of ion implantation when forming a p-type diffusion layer 50, which will be described later. By implanting ions for forming the p-type MISFET source and drain regions, the p-type source and drain regions are formed securely. Preferably, this dose amount and acceleration energy are set smaller than when the n-type source and drain regions 38, 43 are formed, in order to make junction depth of the memory cell shallow and prevent the short channel effect. Consequently, the structure shown in FIG. 12E is formed.

Next, a so-called LDD or extension region may be created by coating with resist 48 and patterning by lithography so as to cover the memory cell region and p-type MISFET region. After that, phosphor ions or arsenic ions are implanted in the dose amount of 2×10¹³(cm⁻²) to 1×10¹⁵(cm⁻²) at the acceleration energy of 5 eV to 50 KeV so as to form the n-type source and drain regions 38. Preferably, this dose amount is set larger than that when forming the n-type source and drain regions 9, 10 in order to drop resistance of the source and drain regions in the peripheral transistor and increase current driving performance. Further, preferably, this dose amount is set smaller than the dose amount for forming the n-type source and drain regions 43, which will be described later, in order to prevent the short channel effect of the peripheral transistor. Consequently, the configuration shown in FIG. 12F is acquired.

Further, it is permissible to create a so-called LDD or extension region by coating with resist 49 and patterning by lithography so as to cover the memory cell region and n-type MISFET region. After that, boron ions or BF₂ ions are implanted in the dose amount of 2×10¹³(cm⁻²) to 1×10¹⁵(cm⁻²) at the acceleration energy of 5 eV to 50 keV so as to form the p-type source and drain regions 50. Preferably, this dose amount is smaller that for the p-type source and drain regions 45 (shown in FIG. 11G) in order to prevent the short channel effect of the peripheral transistor. Consequently, the configuration shown in FIG. 12G is acquired.

After that, for example, a silicon oxide film or silicon nitride film is deposited in the thickness half or more than the interval of the side wall insulation film of an adjacent memory cell, for example in the thickness of 30 to 200 nm and then, anisotropic etching is carried out so as to form the side wall insulation film 41. The insulation film 41 is left between memory cells until it reaches the height of the gate electrode 5 of the memory cell and when implanting ions to the peripheral transistor, acts as a protection film for blocking ions from being implanted into the p-type well. Further, this serves as a side wall for blocking the source and drain regions 43, 45, which are source/drain junction deeper than the LDD or extension portion (38, 50), which is a shallow source/drain junction, from approaching the gate electrode.

Further, resist 51 is applied and patterning is carried out by lithography so as to cover the memory cell region and p-type MISFET region. After that, phosphor ions or arsenic ions are implanted in the dose amount of 1×10¹⁴(cm⁻²) to 1×10¹⁶(cm⁻²) at the acceleration energy of 1 eV to 50 keV so as to form the n-type source and drain regions 43. Consequently, the configuration shown in FIG. 12H is acquired.

Further, resist 52 is applied and patterning is carried out by lithography so as to cover the memory cell region and n-type MISFET region. After that, boron ions or BF₂ ions are implanted in the dose amount of 1×10¹⁴(cm⁻²) to 1×10¹⁶(cm⁻²) at the acceleration energy of 5 eV to 50 keV so as to form the n-type source and drain regions 45. Consequently, the configuration shown in FIG. 12I is acquired. After that, the modification is completed by removing the resist 52.

The modification is capable of securing following effects as well as the effect of the first embodiment and the effects (6), (7) and (8) of the third embodiment.

(11) According to the modification, it is possible to reduce the number of processing steps as compared to the case of coating with resist because it forms the source and drain regions of the MONOS memory cell without applying resist. After a gate electrode is processed, a resist opening in a narrow space portion of the memory cell is not necessary and cheap, long wavelength, for example, positive type resist photo-sensitive to i beam may be used.

(12) Because the impurity densities of the peripheral transistor and the p-type gate electrode in the memory cell region are equal, deflection in etching upon processing of the gate electrode is unlikely to occur, so that damage given to the first insulation layer 2, the electric charge accumulating layer 3, the second insulation layer 4 and the side wall insulation film 8 can be reduced. Thus, a more reliable semiconductor circuit can be achieved.

(13) Thin n-type source and drain regions and a gate electrode having high p-type impurity density necessary for preventing gate depletion can be realized on the same memory cell and the memory cell has a short channel effect and a large current driving ability.

(Fourth Embodiment)

The fourth embodiment refers to a semiconductor memory device, in which surface channel type peripheral transistors comprised of n-type MISFET and p-type MISFET are formed in the same substrate with the memory cell described in the modification of the first embodiment, which will be described below.

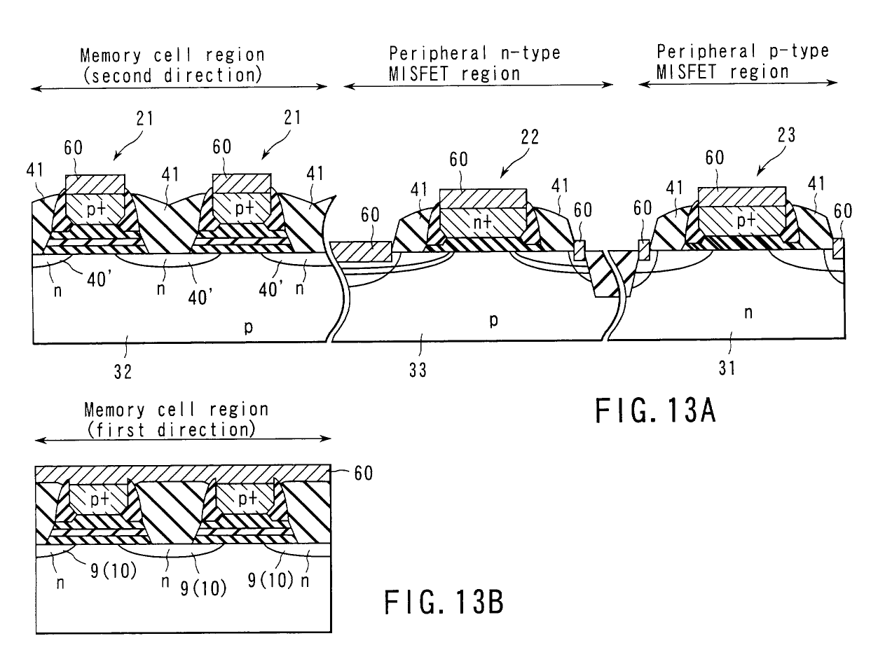

FIGS. 13A and 13B show the element sectional structure of the semiconductor memory device of the fourth embodiment. According to the fourth embodiment, a section of the memory cell region in a second direction, that is, a direction in which the source region, channel region and drain region of the memory cell are extended is indicated while a section in a first direction containing the gate electrode, perpendicular to the second direction is also indicated. In the first direction, two memory cells having a common gate electrode are indicated and the n-type source/drain region 9 (or 10) is formed between the adjacent two memory cells in the first direction. The n-type source/drain region 9 (or 10) is formed so that it is extended in the second direction and connected in parallel to the source/drain region of an adjacent two memory cells in the second direction. Although this example indicates two adjacent memory cells, the number of the memory cells is not restricted to only two but should be plural.

In the semiconductor memory device shown in FIGS. 13A and 13B, a plurality of the memory cells 21 composed of p-type gate MONOS having a shallow n-type source/drain region, a surface channel type n-type MISFET 22 having the n-type gate containing deeper source/drain region and a surface channel type p-type MISFET 23 having the p-type gate containing a source/drain region deeper than the memory cell region are integrated in the same substrate.

Reference numeral 40′ denotes a p-type diffusion region formed in the memory cell region at the same time when the p-type source/drain region is formed and reference numeral 60 denotes salicide formed on the source/drain region of each gate electrode.

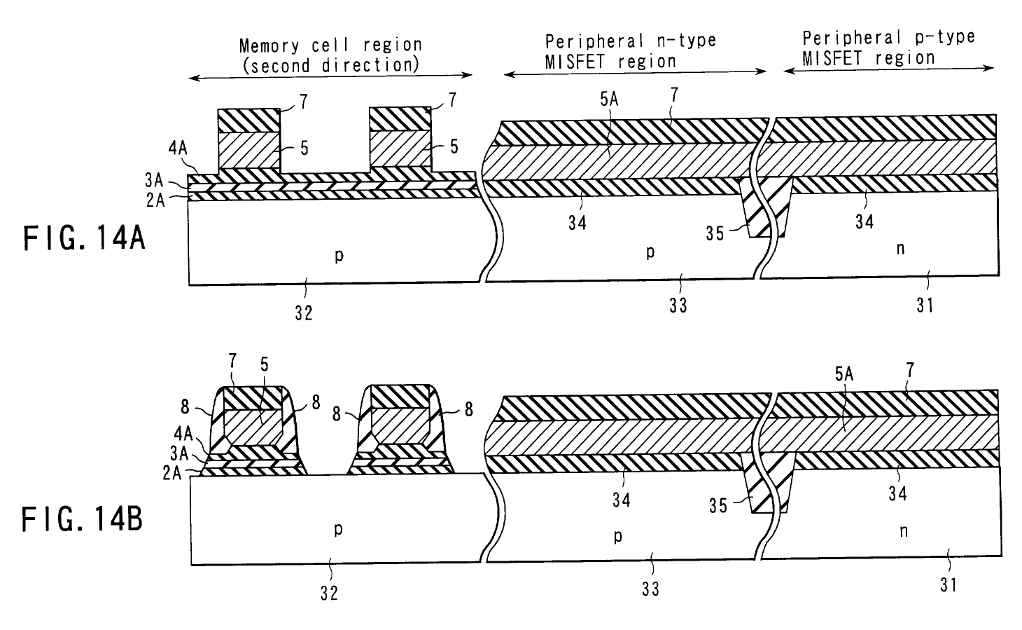

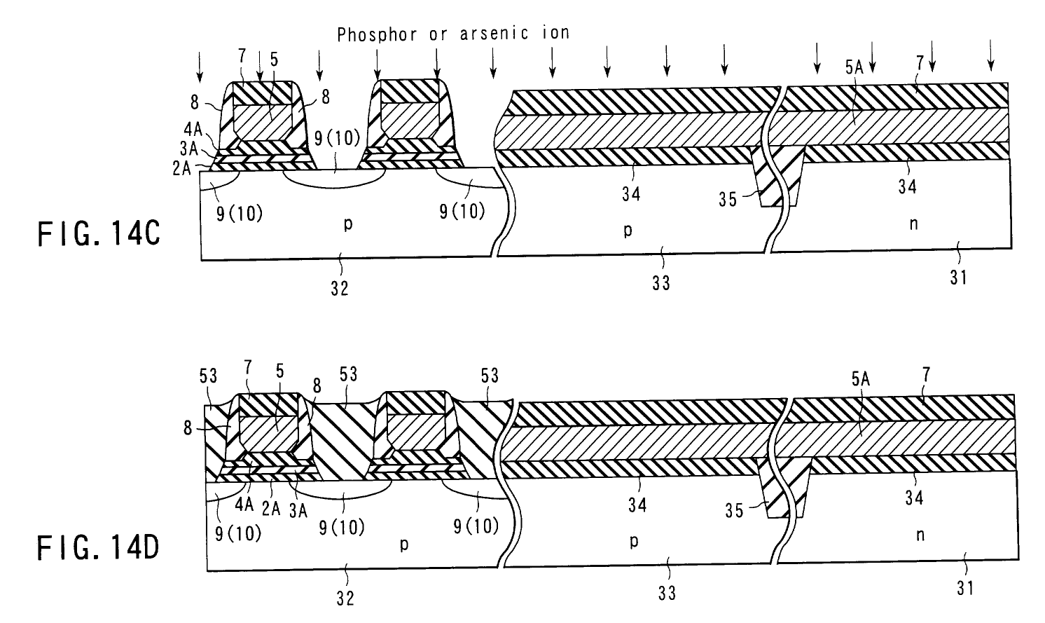

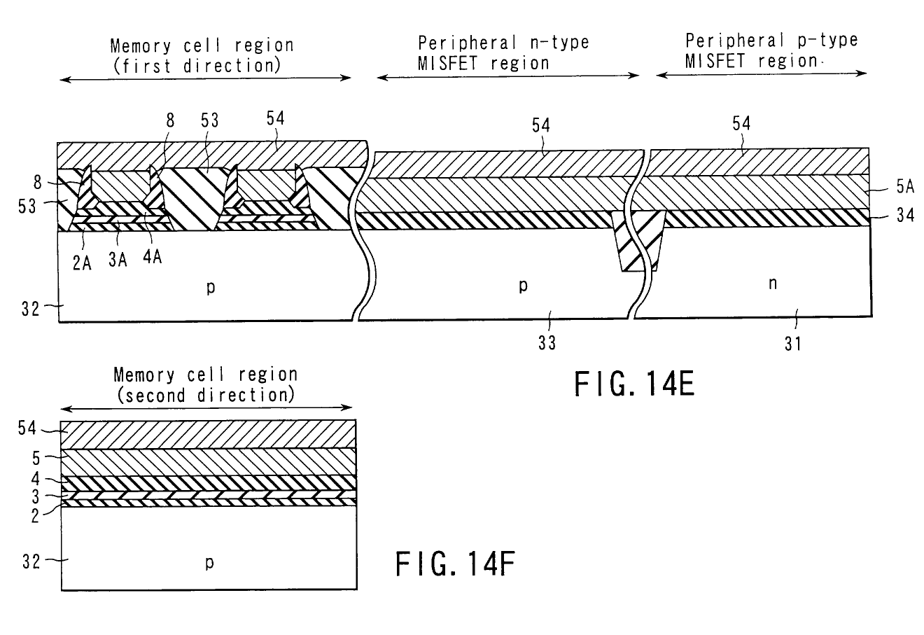

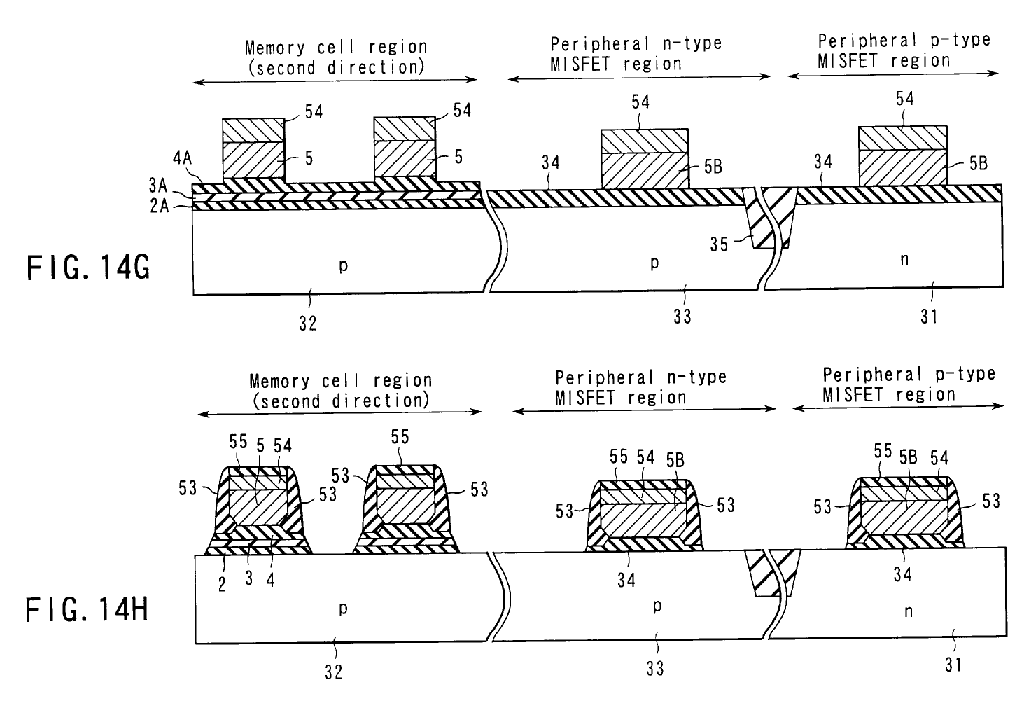

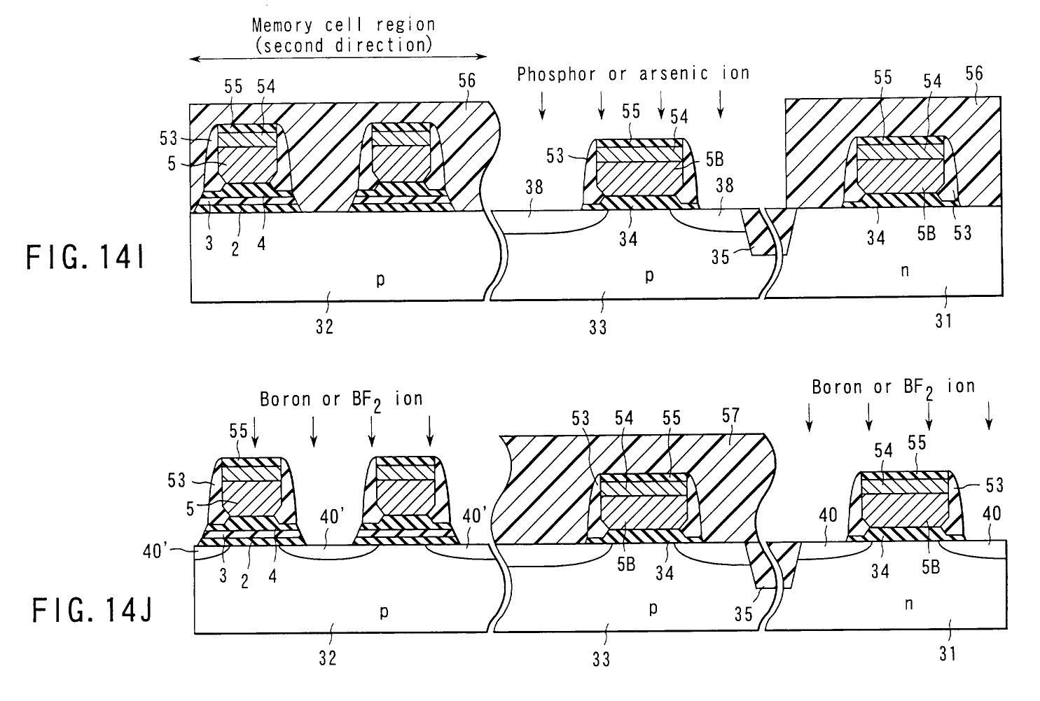

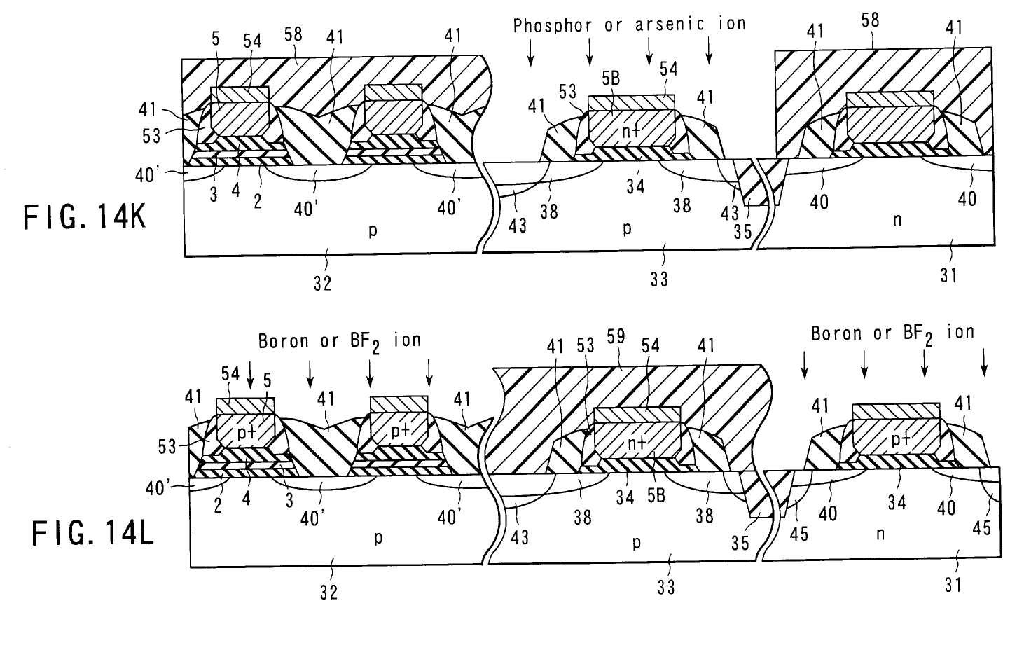

Next, a method of manufacturing the semiconductor memory device shown in FIGS. 13A and 13B will be described with reference to FIGS. 14A to 14L. FIGS. 14A to 14E show sections of the memory cell in the first direction. In FIGS. 14A to 14D, sections in the second direction are the same as that of FIG. 14F and therefore, representation thereof is omitted. FIGS. 14F to 14L show sections of the memory cell in the second direction. In FIGS. 14F to 14L, sections in the first direction are the same as that of FIG. 14F and therefore, representation thereof is omitted.

Processing until the amorphous silicon film or polycrystalline silicon film 5A is deposited on the entire surface in the thickness of 10 to 500 nm is the same as the third embodiment. Preferably, the film 5A should be film which n-type or p-type impurity is not doped intentionally in order to add the n-type and p-type impurity thereto later to form the p-type and n-type gate electrodes.

Next, a silicon oxide film or nitride film 7, which acts as a mask material is deposited on the entire surface in the thickness of 10 to 500 nm. After this, lithography and anisotropic etching are carried out in the memory cell region so as to process the films linearly and vertically in the second direction and the etching is stopped by the silicon oxide film 34 and the silicon oxide film or oxynitride film 4A, thereby the configuration shown in FIG. 14A is obtained. At this moment, preferably, etching for gate side wall processing is stopped with the silicon oxide film or oxynitride film 4A in order to reduce processing damage to the silicon nitride film 3A which acts as the electric charge accumulating layer 3. Particularly, the structure in which the thickness of the second insulation film (silicon oxide film or oxynitride film 4A), which constitutes the gate insulation film of the memory cell, is as large as 5 nm, is capable of stopping etching more easily than the conventional example. At this moment, according to the embodiment, the peripheral transistor does not have to be processed with lithography as shown in FIG. 14A.

Further, for example, a silicon oxide film having a thickness of 2 to 300 nm is formed as the side wall insulation film 8 by annealing in oxidizing environment so as to reduce defect in the surface of the semi-conductor substrate. It is permissible to deposit a silicon oxide film or silicon nitride film composed of, for example, TEOS or HTO, as the side wall insulation film 8 in the oxidizing step. After that, with the side wall insulation film 8 as a mask, the silicon oxide film or oxynitride film 2A, the silicon nitride film 3A and the silicon oxide film or oxynitride film 4A are removed selectively in the first direction. Consequently, the structure shown in FIG. 14B is formed.

After that, phosphor ions or arsenic ions are implanted in the dose amount of 1×10¹³(cm⁻²) to 1×10¹⁵(cm⁻²) at the acceleration energy of 1 eV to 50 keV so as to form the n-type source/drain region 9 (or 10). In this case, because the silicon film 5A, and the silicon oxide film or nitride film 7 are not patterned in the peripheral MISFET, implanted ions remain at the silicon oxide film or nitride film 7 and do not reach the n-type well 31 and the p-type well 33, so that the source/drain region 9 (or 10) can be formed selectively in the memory cell region. Preferably, the dose amount and acceleration energy are set smaller than n-type source/drain regions 38, 43 to be formed later, in order to make small memory cell junction depth thereby blocking the short channel effect. Consequently, the structure shown in FIG. 14C is formed.

Thereafter, for example, a silicon oxide film or silicon nitride film is deposited in the thickness half or more than the interval of the side wall insulation film of an adjacent memory cell, for example in the thickness of 30 to 200 nm and then, anisotropic etching is carried out so as to form a side wall insulation film 53. The insulation film 53 is left between memory cells until it reaches the height of the gate electrode of the memory cell and when implanting ions to the peripheral transistor, acts as a protection film for blocking ions from being implanted into the source/drain region of the cell transistor. Consequently, the structure shown in FIG. 14D is formed.

Subsequent to the process for forming the side wall insulation film 53, the insulation film 7 formed on the amorphous silicon film or polycrystalline silicon film 5A is removed. Further, an amorphous silicon film or polycrystalline silicon film 54 is deposited on the entire surface in the thickness of 10 to 500 nm. Preferably, the silicon film 54 is a film which n-type or p-type impurity is not doped intentionally in order to add the n-type and p-type impurity thereto later to form the p-type and n-type gate electrodes. Consequently, the structure shown in FIGS. 14E and 14F is formed.

Then, lithography and anisotropic etching are carried out in the memory cell region and peripheral transistor so as to process the amorphous silicon film or polycrystalline silicon film 5A and the amorphous silicon film or polycrystalline silicon film 54 linearly and vertically in the first direction. By stopping etching with the silicon oxide film 34 and the silicon oxide film or oxynitride film 4A, the configuration shown in FIG. 14G is acquired. At this moment, etching for the gate side wall processing is stopped with the silicon oxide film or oxynitride film 4A in order to minimize processing damage to the silicon nitride film 3A, which serves as the electric charge accumulating layer 3. Particularly, the structure in which the thickness of the second insulation film (silicon oxide film or oxynitride film 4A), which constitutes the gate insulation film of the memory cell, is as large as 5 nm, is capable of stopping etching more easily than the conventional example.

Further, for example, a silicon oxide film having a thickness of 2 to 300 nm is formed as the side wail insulation film 53 by annealing in oxidizing environment so as to reduce surface defect of the semiconductor substrate. At this moment, the gate electrode is also oxidized so that a top insulation film 55 is formed in the thickness of 2 to 300 nm. It is permissible to deposit a silicon oxide film or silicon nitride film composed of, for example, TEOS or HTO, as the side wall insulation film 53 in this oxidizing step. After this, with the side wall insulation film 53 as a mask, the silicon oxide film or oxynitride film 2A, the silicon nitride film 3A and the silicon oxide film or oxynitride film 4A are removed selectively so as to form the first insulation layer 2, the electric charge accumulating layer 3 and the second insulation layer 4 in the memory cell transistor. Consequently, the structure shown in FIG. 14H is formed.

In addition, it is permissible to create a so-called LDD or extension region by coating with resist 56 and patterning by lithography so as to cover the memory cell region and p-type MISFET region. After this, phosphor ions or arsenic ions are implanted in the dose amount of 2×10¹³ (cm⁻²) to 1×10¹⁵(cm⁻²) at the acceleration energy of 5 eV to 50 keV so as to form the n-type source/drain regions 38. Preferably, the dose amount should be set larger than when the n-type source/drain region 9 (or 10) are formed, in order to drop the source/drain resistance of the peripheral transistor and increase current driving ability. Further, preferably, this should be set smaller than when the n-type source/drain regions 43 are formed, in order to block the short channel effect of the peripheral transistor. Consequently, the configuration shown in FIG. 14I is acquired.

Further, it is permissible to create a so-called LDD or extension region by coating with resist 57 and patterning by lithography so as to cover only the n-type MISFET region. After this, boron ions or BF₂ ions are implanted in the dose amount of 2×10¹³(cm⁻²) to 1×10¹⁵(cm⁻²) at the acceleration energy of 5 eV to 50 keV so as to form the p-type source/drain regions 40 and diffusion regions 40′. Preferably, the dose amount should be set smaller than when the p-type source/drain regions 45 to be described later are formed, in order to block the short channel effect of the peripheral transistor. At the same time, the p-type impurity is implanted into the p-type well 32 in the second direction of the memory cell region so that p-type diffusion regions 40′ are formed. The p-type diffusion regions 40′ acts as punch through stopper between adjacent n-type source/drain regions 9 (or 10). Consequently, the configuration shown in FIG. 14J is acquired.

After that, for example, a silicon oxide film or silicon nitride film is deposited in the thickness half or more than the interval of the side wall insulation film of an adjacent memory cell, for example in the thickness of 30 to 200 nm and then, anisotropic etching is carried out so as to form the side wall insulation film 41. The insulation film 41 is left between memory cells until it reaches the height of the gate electrode 5 of the memory cell and when implanting ions to the peripheral transistor, acts as a protection film for blocking ions from being implanted. Further, the insulation film 41 acts as a side wall for preventing source/drain regions 43, 45 deeper than the LDD which is a shallow source/drain junction or extension portions 38, 50 from approaching the gate electrode. The insulation film 55 formed on the gate electrode 5 is removed after the process for forming this side wall insulation film 41.

Further, resist 58 is applied and patterning is carried out by lithography so as to cover the memory cell region and p-type MISFET region. After this, phosphor ions or arsenic ions are implanted in the dose amount of 1×10¹⁴(cm⁻²) to 1×10¹⁶(cm⁻²) at the acceleration energy of 1 eV to 50 keV so as to form the n-type source/drain regions 43. The n-type gate electrode is obtained by doping n-type impurity to the gate electrode 5B in the n-type MISFET region at the same time. Consequently, the configuration shown in FIG. 14K is acquired.

Further, resist 59 is applied and patterning is carried out by lithography so as to cover the n-type MISFET region. After this, boron ions or BF₂ ions are implanted in the dose amount of 1×10¹⁴(cm⁻²) to 1×10¹⁶(cm⁻²) at the acceleration energy of 1 eV to 50 keV so as to form the p-type source/drain regions 45. At this moment, acceleration energy is selected so that the implanted ions do not reach the p-type well 32. In this process, the p-type gate electrode can be obtained by doping the p-type impurity to the memory cell region and p-type MISFET region. It is more preferable to use boron than BF₂ as the implantation ion, because the phenomenon that boron doped to the gate electrode oozes to the n-type well 31 is restricted. Consequently, the configuration of FIG. 14L is acquired.

After metal for creating silicide such as Ti, Co, Ni, or Pd is deposited in the entire range of 1 to 40 nm, a heating step of 400 to 1,000° C. is added so as to form silicide. After that, remaining metals are etched by etching with sulfuric acid and peroxide solution so as to form salicide 60 as shown in FIGS. 13A and 13B.

The fourth embodiment acquires following effects as well as the effect of the modification of the first embodiment, the effect of the second embodiment and the effects (6), (7), (8), (9) and (10) of the third embodiment.

(14) In the memory cell region, a memory cell can be formed self aligningly in an intersection area between the linear pattern of the gate electrode 5 and the linear pattern of the amorphous silicon film or polycrystalline silicon film 54. Consequently, a high-density memory cell specified by minimum wiring pitch can be realized. Further, the electric charge accumulating layer 3 can be formed without deflecting from the p-type well 32, the n-type source/drain region 9 (or 10) and the p-type diffusion regions 40′, so that more uniform capacities of the electric charge accumulating layer 3 and p-type well 32 can be realized. Consequently, deflection in the capacity of the memory cell or deflection in the capacity between the memory cells can be reduced.

(Fifth Embodiment)

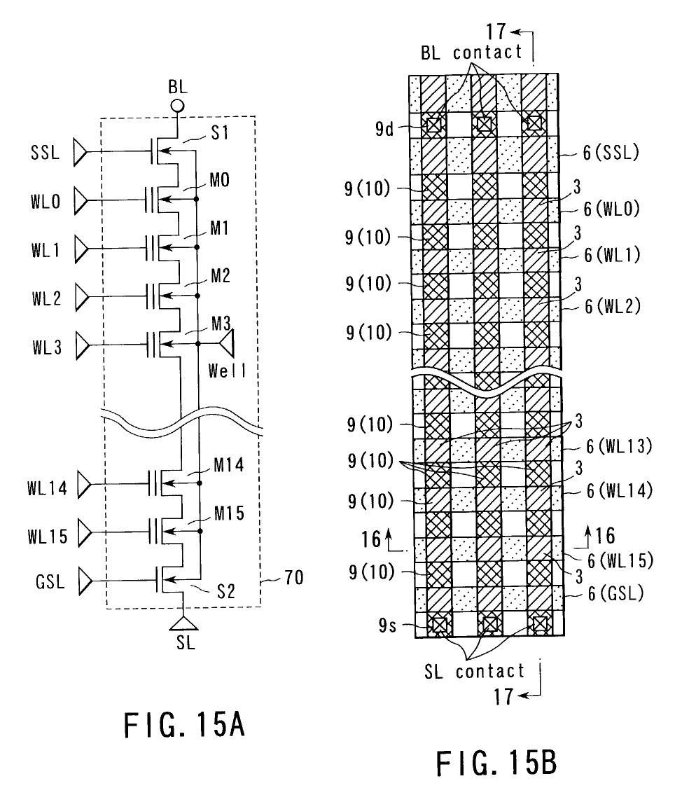

FIGS. 15A, 15B, 16 and 17 show the structure of a semiconductor memory device according to a fifth embodiment of the present invention. The fifth embodiment shows a NAND cell array in which a plurality of the memory cells described in the above-described respective embodiments are connected in series. In the meantime, like reference numerals are attached to portions corresponding to the first to fourth embodiments and description thereof is omitted.

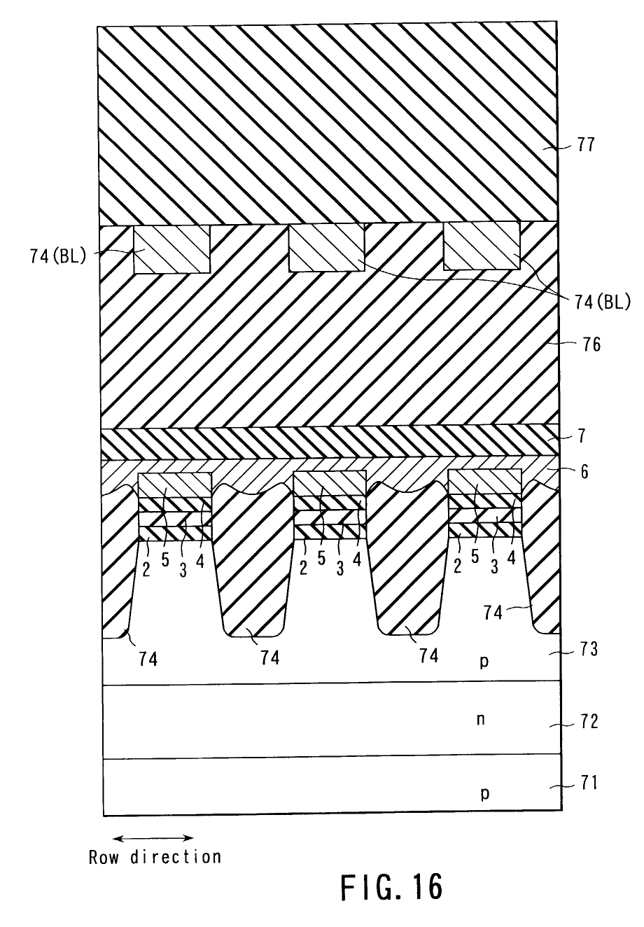

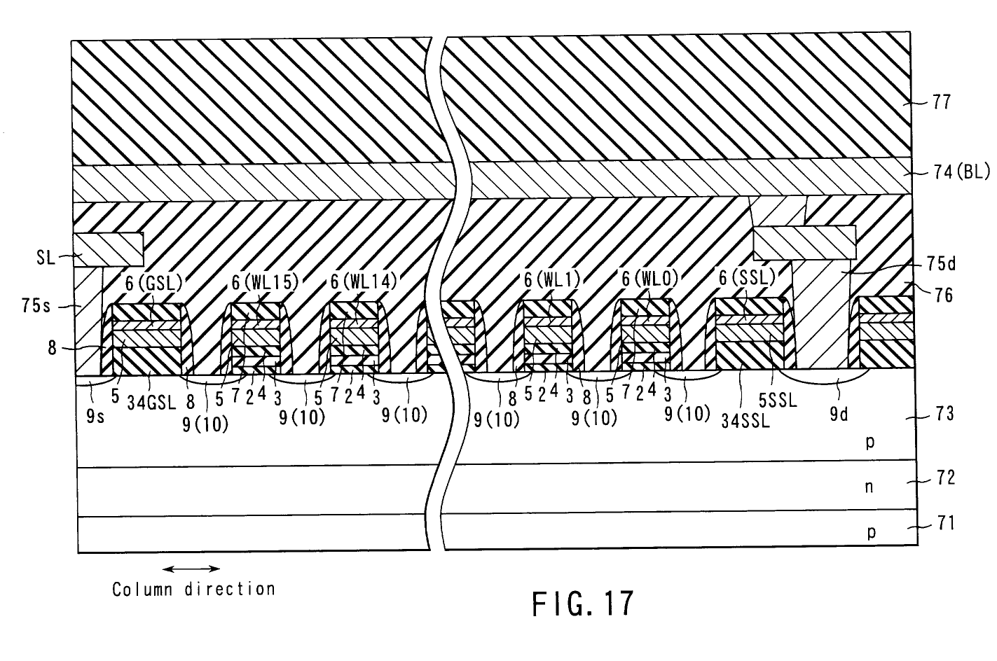

FIG. 15A is a circuit diagram of a memory block 70 and FIG. 15B is a plan view of a case where three memory blocks 70 shown in FIG. 15A are placed in parallel. FIG. 15B indicates only a structure below the metallic lining layer 6 which acts as a gate control line to facilitate understanding of the cell structure. FIG. 16 shows the device sectional structure taken along the line 16-16 of FIG. 15B and FIG. 17 shows the device sectional structure taken along the line 17-17 of FIG. 15B.

Referring to FIG. 15A, nonvolatile memories M0 to M15 composed of a field effect transistor which employs for example, a silicon nitride film or silicon oxynitride film as its electric charge accumulating layer are connected in series and an end thereof is connected to a data transmission line (bit line) BL through a first select transistor S1. The other end is connected to a common source line SL through a second select transistor S2. The respective transistors are formed on the same well.

Referring to FIGS. 16 and 17, an n-type well 72 is formed on a p-type silicon substrate 71 and a p-type well 73 containing boron impurity density of 10¹⁴(cm⁻²) to 10¹⁹(cm⁻²) is formed on the n-type well 72. The electric charge accumulating layer 3 composed of, for example, a silicon nitride film or silicon oxynitride film is formed on the p-type well 73 in the thickness of 3 to 50 nm through the first insulation layer 2 composed of a silicon oxide film or oxynitride film having a thickness of 0.5 to 10 nm. The gate electrode 5 composed of, for example, a p-type polycrystalline silicon layer is formed thereon through the second insulation layer 4 composed of a silicon oxide film having a thickness of 5 to 30 nm. Further, the metallic lining layer 6 composed of a stack structure consisting of WSi (tungsten silicide) and polycrystalline silicon or any one of W, NiSi, MoSi, TiSi and CoSi and polycrystalline silicon is formed thereon as a gate control line in the thickness of 10 to 500 nm.

As a memory cell having such a structure, the memory cell described in the first embodiment to fourth embodiment may be used.

The plural gate control lines each composed of the metallic lining layer 6 are extended to the boundary of the block in the right/left direction of this paper so that each thereof is connected between adjacent memory cell blocks as shown in FIG. 15B. These plural gate control lines form data select lines (word lines) WL0 to WL15 and select gate control lines SSL, GSL. Because the p-type well 73 is separated from the p-type silicon substrate 71 by the n-type well 72, voltage can be applied to the p-type well 73 independently of the p-type silicon substrate 71. Preferably, such a structure reduces load on a voltage boosting circuit at the time of erasing so as to suppress power consumption.

The p-type well 73 is formed self aligningly in a region in which an element isolating insulation film 74 of a silicon oxide film is not formed. After layers for forming the first insulation layer 2, the electric charge accumulating layer 3 and the second insulation film 4 are deposited in the p-type well 73, those layers are patterned. The p-type well 73 is etched in the depth of, for example, 0.05 to 0.5 μm until it reaches the p-type well 73 and then, the insulation film 74 is buried.

The source/drain region 9 (or 10) is formed across the insulation film 8 composed of a silicon nitride film or silicon oxide film having a thickness of, for example, 5 to 200 nm on both sides of the gate electrode 5. The MONOS type nonvolatile EEPROM memory cell is formed of the source/drain region 9 (or 10), the electric charge accumulating layer 3 and the gate electrode 5 and the gate length of the electric charge accumulating layer is 0.01 μm or more and 0.5 μm or less. The source/drain region 9 (or 10) is formed at a position 10 to 500 nm deep so that the surface density of phosphor, arsenic and antimony is 10¹⁷ (cm⁻³) to 10²¹ (cm⁻³) Further, the source/drain regions 9 and 10 are connected in series among memory cells so as to achieve the NAND array. In FIG. 17, reference numerals 6(SSL) and 6(SL) denote block select lines corresponding to SSL and GSL respectively, which are formed in the same conductive layer as the gate control line (metallic lining layer 6) in the EEPROM memory cell. The gate electrode 5 opposes the p-type well 73 through gate insulation films 34SSL and 34GSL composed of a silicon oxide film or oxynitride film having a thickness of, for example, 3 to 15 nm. Here, the gate length of gate electrodes 5SSL and 5GSL is larger than the gate length of the gate electrode in the memory cell and by forming in 0.02 μm or more and 1 μm or less, a large ON/OFF ratio about block selection and non-selection can be secured, thereby preventing write error and read error.

If the same p-type electrode as in the memory cell is employed for the gate electrodes 5SSL and 5GSL, depletion in the gate electrode of the memory cell and gate electrodes 5SSL and 5GSL of the select transistor due to mutual diffusion of impurity can be blocked and relating processing steps can be reduced.

An n-type source/drain region 9d formed on a side of the gate electrode 5SSL is connected to a data transmission line 74 (BL) composed of, for example, W, tungsten silicide, Ti, titan nitride, Cu or Al through a contact 75d. The data transmission line 74 (BL) is formed up to block boundaries in the vertical direction of this paper in FIG. 15B so that it is connected between adjacent memory cell blocks. On the other hand, a source/drain region 9s formed on a side of the gate electrode 5GSL is connected to a common source line SL through a contact 75s. This common source line SL is formed up to block boundaries in the right/left directions of this paper in FIG. 15B so that it is connected between adjacent memory cell blocks. Of course, it is permissible to form the n-type source/drain region 9s up to block boundaries in the right/left direction of this paper as the common source line.

The BL contact and SL contact are filled with, for example, n-type or p-type doped polycrystalline silicon, tungsten, tungsten silicide or Al, TiN, Ti, and serve as a conductive region. Further, an interlayer film 76 composed of a silicon oxide film, silicon nitride film or the like is filled among the common source line SL, data transmission line BL and the transistor. An insulation protecting layer 77 composed of, for example, a silicon oxide film, silicon nitride film or polyimide and top wiring (not shown) composed of, for example, W, Al, Cu or the like are formed on the top of the data transmission line BL.

According to the fifth embodiment, the p-type well 73 is employed in common and by tunnel implantation through the p-type well, plural cells can be erased at the same time. Thus, in addition to the effects of the first embodiment to the fourth embodiment, power consumption at the time of erasing can be suppressed and many bits can be erased in batch quickly.

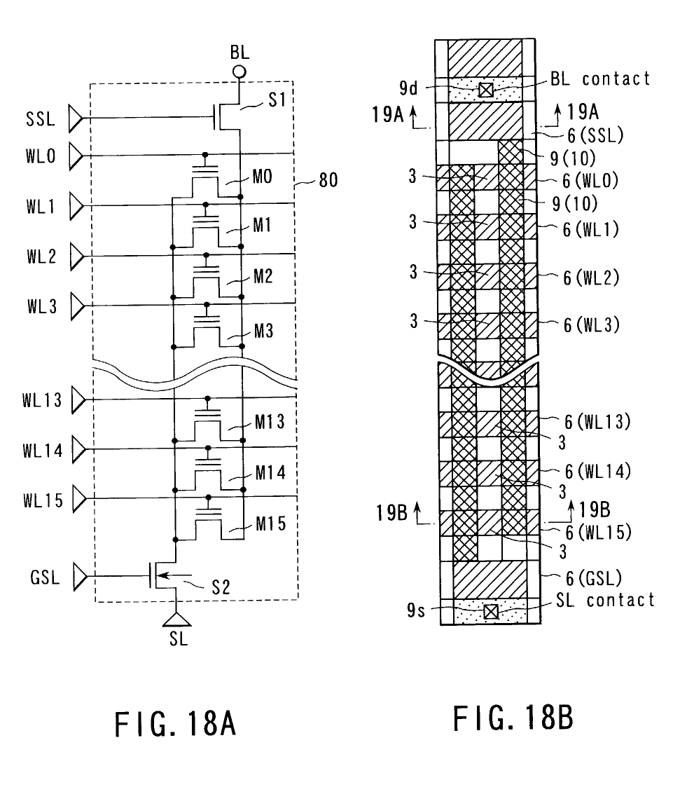

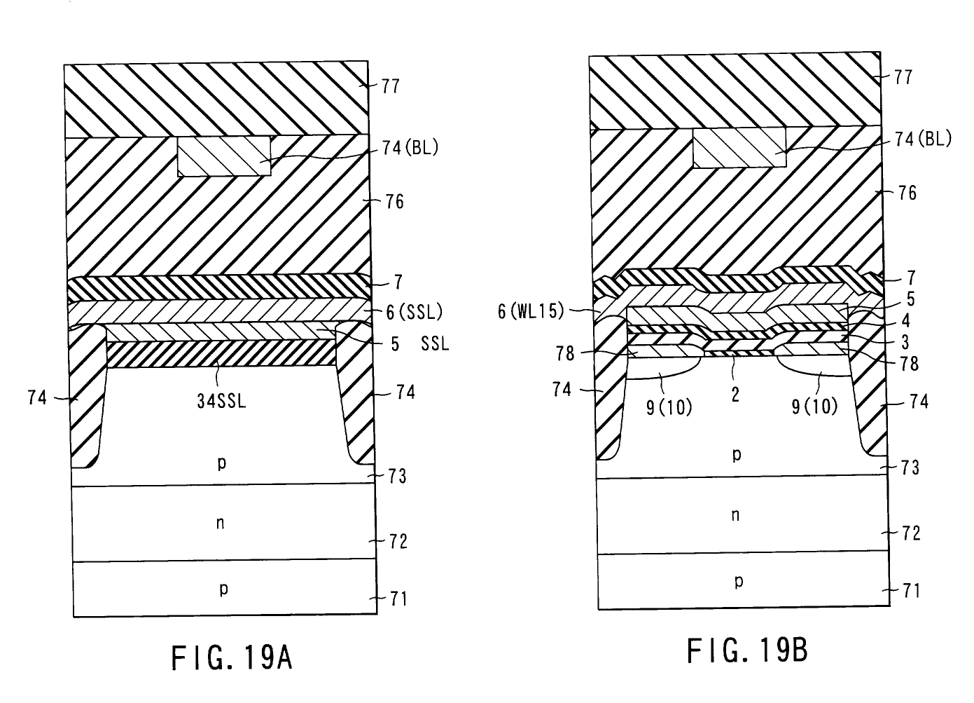

(Sixth Embodiment) FIGS. 18A, 18B, 19A and 19B show the structure of a semiconductor memory device according to a sixth embodiment of the present invention. The sixth embodiment indicates an AND cell array in which the memory cells described in the first embodiment to fourth embodiment are connected in series. In the meantime, like reference numerals are attached to portions corresponding to the first to fourth embodiments and description thereof is omitted.

FIG. 18A is a circuit diagram of a memory block 80. Referring to FIG. 18A, plural nonvolatile memory cells M0 to M15 each composed of an electric field effect transistor which employs a silicon nitride film or silicon oxynitride film as its electric charge accumulating layer are connected through their current terminals in parallel. An end thereof is connected to the data transmission line (bit lone) BL through a first block select transistor S1 while the other end is connected to the common source line SL through a second block select transistor S2. The respective transistors are formed in the same well. When “n” is regarded as block index (natural number), the gate electrode of each of the memory cells M0 to M15 is connected to the data select lines (word lines) WL0 to WL15. Further, because one memory cell block is selected from plural memory cell blocks along the data transmission line BL and connected to the data transmission line, the gate electrode of the first block select transistor S1 is connected to the block select line SSL. Further, the gate electrode of the second block select transistor S2 is connected to the block select line GSL. As a result of such connection, a so-called AND type memory cell block 80 is formed.

According to the sixth embodiment, the control wirings SSL and GSL of the block select gate are formed with wirings in the same layer as the control wirings WL0 to WL15 in the memory cell. The memory cell block 80 only has to contain at least a block select line and preferably is formed in the same direction as the data select line for high density.

The sixth embodiment indicates a case where memory cells of 16=2⁴ are connected within the memory cell block 80. The number of the memory cells to be connected to the data transmission line and data select line only should be plural and is preferred to be 2ⁿ (n is a positive integer) for address decoding.

FIG. 18B shows a plan view of the memory block 80 in FIG. 18A. FIG. 18B indicates only the structure below the metallic lining layer 6 which serves as a gate control line to facilitate understanding of the cell structure. FIG. 19A shows an element sectional structure taken along the line 19A-19A of FIG. 18B and FIG. 19B shows an element sectional structure taken along the line 19B-19B of FIG. 18B.

Referring to FIGS. 19A and 19B, the n-type well 72 is formed on the p-type silicon substrate 71. Further, the p-type well 73 is formed on the n-type well 72. The electric charge accumulating layer 3 composed of, for example, a silicon oxide film or silicon oxynitride film is formed on the p-type well 73 in the thickness of 3 to 50 nm through the first insulation layer 2 composed of, for example, a silicon oxide film or oxynitride film having a thickness of 0.5 to 10 nm. The gate electrode 5 composed of, for example, a p-type polycrystalline silicon layer is formed thereon through the second insulation layer 4 composed of a silicon oxide film having a thickness of 5 to 30 nm. These layers are formed self aligningly with the p-type well 73 in a region in which the element isolating insulation film 74 composed of a silicon oxide film is not formed.

After multi-layered films for forming the first insulation layer 2, the electric charge accumulating layer 3 and the second insulation film 4 are deposited on the p-type well 73, patterning is carried out. Then, this etching is executed in the depth of 0.05 to 0.5 μm until the etching depth reaches the p-type well 73 and the insulation film 74 is buried therein. Because the first insulation film 2, the electric charge accumulating layer 3 and the second insulation layer 4 are formed in flat planes having little step, uniformity is improved and characteristics of the films match each other. An interlayer insulation film 78 and n-type source/drain region 9 (or 10) in the memory cell are formed self aligningly before the tunnel insulation film (second insulation layer 4) is formed. Mask material is formed of polycrystalline silicon on a portion in which the first insulation layer 2 is to be formed, n-type diffusion is carried out by ion implantation so as to deposit the interlayer insulation film 78 on the entire surface and then, the mask material corresponding to a portion in which the interlayer insulation film 78 is to be left is removed selectively by CMP and etch back. It is permissible to use the memory cell described in the first embodiment to the fourth embodiment as the memory cell for use.

Further, the metallic lining layer 6 constituted of a stack structure of WSi (tungsten silicide) and polycrystalline silicon or stack structure of any one of W, NiSi, MoSi, TiSi and CoSi and polycrystalline silicon is formed as a gate control line in the thickness of 10 to 500 nm. A plurality of the control lines are formed up to block boundaries in the right/left direction of this paper so that each thereof is connected through adjacent memory cell blocks. The plural control lines constitute data select lines WL0 to WL15 and block selection gate control lines SSL and GSL.

In this case also, the p-type well 73 is separated from the p-type silicon substrate 71 by the n-type well 72. Thus, the p-type well 73 can be supplied with voltage independently of the p-type silicon substrate 71, thereby leading to reduction of load on a voltage boosting circuit at the time of erasing and suppression of power consumption.

As shown in FIG. 19B, the n-type source and drain regions 9 10 are formed across the interlayer insulation film 78 composed of a silicon oxide film or oxynitride film having a thickness of, for example, 5 to 200 nm below the gate electrode 5. The MONOS type EEPROM memory cell which handles the amount of electric charges accumulated in the electric charge accumulating layer 3 as the amount of information is formed of the source and drain regions 9, 10, the electric charge accumulating layer 3 and the gate electrode 5. The length of the memory cell is 0.01 μm and 0.5 μm or less. Preferably, the interlayer insulation film 78 should be formed over the source and drain regions 9, 10 and extended over the channel so as to prevent write error due to concentration of electric field at ends of the source and drain regions.

The source and drain regions 9, 10 are formed at a position 10 to 500 nm deep so that for example, the surface density of phosphor, arsenic or antimony is 10¹⁷ (cm⁻³) to 10²¹ (cm⁻³). The source and drain regions 9, 10 are shared between adjacent memory cells in the data transmission line BL, so that an AND type cell array structure is achieved.

Referring to FIG. 18B, reference numerals 6(SSL) and 6(SL) denote control lines connected to block selection lines corresponding to SSL and GSL respectively, which are formed in the same conductive layer as the control lines WL0 to WL15 in the MONOS type EEPRPM memory cell.

As shown in FIGS. 18B and 19A, one block select transistor S1 is formed as a MOSFET in which reference numerals 9 (or 10) and 9d denote source/drain regions while reference numeral 6 (SSL) denotes a gate electrode. The other block select transistor S2 is formed as a MOSFET in which reference numerals 9 (or 10) and 9s denote source/drain regions while reference numeral 6(GSL) denotes a gate electrode. The length of each of the gate electrodes 6(SSL) and 6(GSL) is larger than that of the gate electrode in the memory cell. For example, if they are formed in 0.02 μm or more and 1 μm or less, a large ON/OFF ratio about block selection and non-selection can be secured, thereby preventing write error and read error.

If the same p-type electrode as in the memory cell is employed for the gate electrodes 5SSL and 5GSL, depletion in the gate electrode of the memory cell and gate electrodes SSL and GSL due to mutual diffusion of impurity can be blocked and relating processing steps can be reduced.

According to the sixth embodiment, the p-type well 73 is employed in common and by tunnel implantation through the well, plural cells can be erased at the same time. Thus, in addition to the effects of the first embodiment to the fourth embodiment, power consumption at the time of erasing can be suppressed and many bits can be erased in batch quickly.

Because the sixth embodiment uses the AND type cell, the series resistance of the memory cell block can be reduced to a predetermined value, so that it is suitable for stabilizing the threshold value when storage data is turned to multiple-value.

The connection method for connecting the source and drain of a memory cell of the sixth embodiment in parallel can be adapted to the virtual ground array type EEPROM, and the same effect is produced.

According to the sixth embodiment, because the memory cells are connected in parallel to each other, in addition to the effects of the first embodiment to the fourth embodiment, a large cell current is secured and high-speed data readout is achieved.

(Seventh Embodiment)

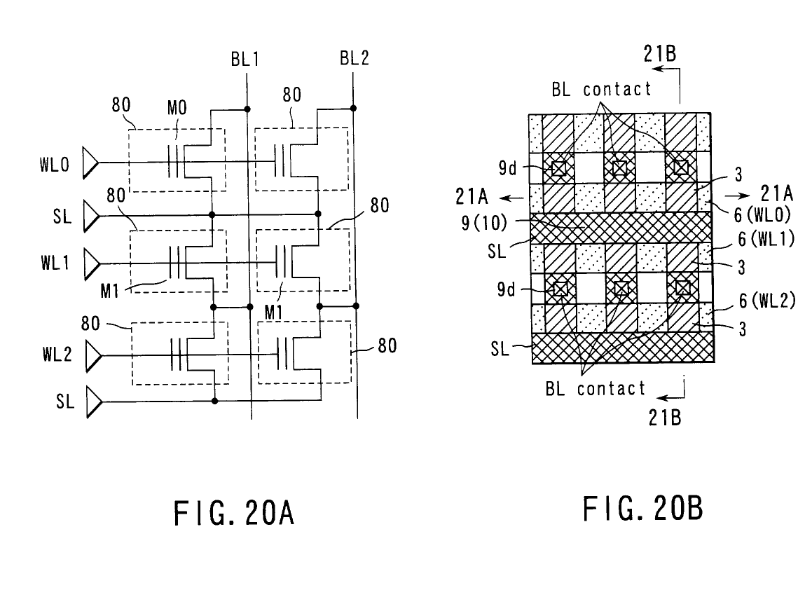

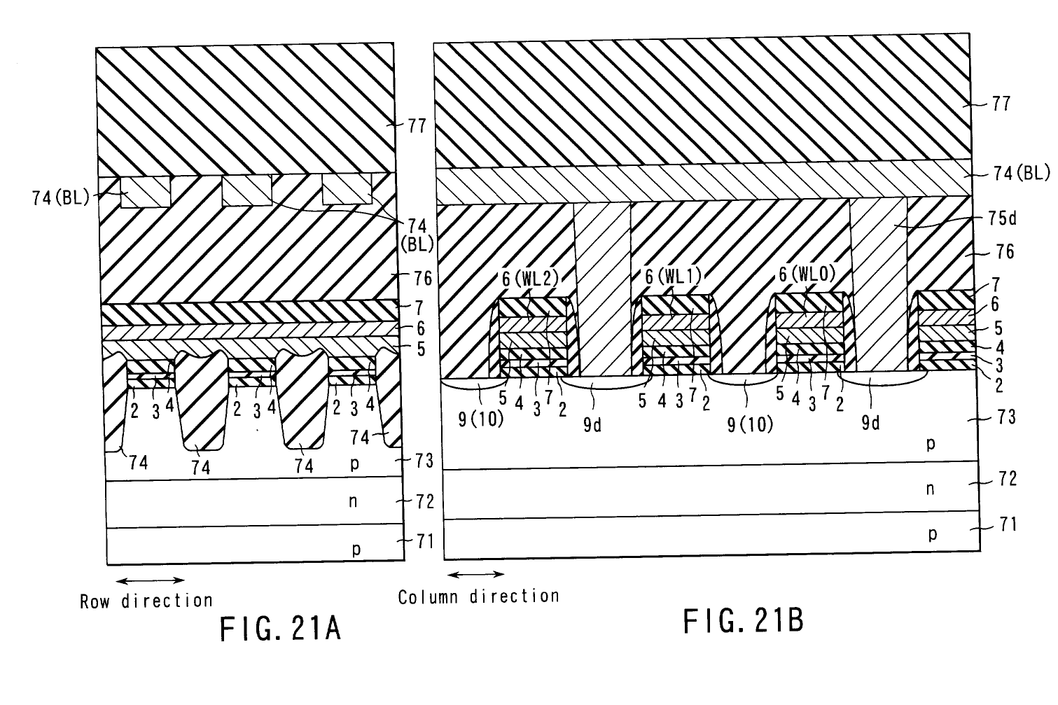

FIGS. 20A, 20B, 21A and 21B show the structure of a semiconductor memory device according to a seventh embodiment of the present invention. The seventh embodiment indicates a NOR cell array block employing the MONOS memory cell described in the first embodiment to the fourth embodiment. FIG. 20A is a circuit diagram of the NOR cell array block, FIG. 20B is a plan view thereof, FIG. 21A is a sectional view (sectional view taken along the line 21A-21A in FIG. 20B) of the memory cell in the row direction and FIG. 21B is a sectional view (sectional view taken along the line 21B-21B in FIG. 20B) of the memory cell in the column direction. Particularly, FIG. 20B shows only the structure below the gate control line composed of the metallic lining layer 6 to facilitate understanding of the cell structure. Like reference numerals are attached to portions corresponding to the first to fourth embodiments and description thereof is omitted.

Referring to FIG. 20A, a plurality of nonvolatile memory cells M0 to Mi, each composed of a field effect transistor which employs, for example, a silicon nitride film or silicon oxynitride film as its electric charge accumulating layer are connected in parallel through their current terminals. An end of the plural nonvolatile memory cells M0 to Mi connected in parallel is connected to the data transmission line BL, while the other end thereof is connected to a common source line SL. In the NOR memory cell, a memory cell block 80 is formed of a single transistor. Each transistor is formed in the same well. Each gate electrode of the memory cells M0 to Mi is connected to the data select lines WL0 to WL2.

Referring to FIGS. 21A and 21B, the electric charge accumulating layer 3 composed of, for example, a silicon oxide film or silicon oxynitride film is formed in the thickness of 3 to 50 nm on the p-type well 73 containing the impurity density of 10¹⁴ (cm⁻³) to 10¹⁹ (cm⁻³) through the first insulation film 2 composed of a silicon oxide film or oxynitride film having a thickness of, for example, 0.5 to 10 nm. The gate electrode 5 composed of, for example, a p-type polycrystalline silicon is formed thereon through the second insulation film 4 composed of a silicon oxide film having a thickness of 5 nm or more and 30 nm or less. Further, a gate control line is formed thereon in the thickness of 10 to 500 nm with the metallic lining layer 6 constituted of a stack structure of WSi (tungsten silicide) and polycrystalline silicon or stack structure of any one of W, NiSi, MoSi, TiSi and CoSi and polycrystalline silicon.

As the above-mentioned memory cells M0 to Mi, the MONOS memory cell described in the first to fourth embodiments may be used. As shown in FIG. 20B, plural gate control lines composed of the metallic lining layer 6 are formed up to block boundaries in the right/left direction of this paper so that each thereof is connected through adjacent memory cell blocks. These plural gate control lines form data select lines WL0 to WL2. Because the p-type well 73 is separated from the p-type silicon substrate 71 by the n-type well 72, the p-type well 73 may be supplied with voltage independently of the p-type silicon substrate 71. Preferably, such a structure reduces load on a voltage boosting circuit at the time of erasing, thereby suppressing power consumption.

As shown in FIG. 21B, the n-type source/drain region 9 (or 10) is formed in each of the p-type wells 73 on both side faces of the gate electrode 5. The MONOS type EEPROM memory cell, which handles the amount of electric charges accumulated in the electric charge accumulating layer as the amount of information, is formed of the source/drain region 9 (or 10), the electric charge accumulating layer 3 and the gate electrode 5. The length of this EEPROM memory cell is 0.01 μm or more and 0.5 μm or less.

As shown in FIGS. 20B and 21B, the data transmission line 74 (BL) is connected to the n-type source/drain region 9d, while the source/drain region 9 (or 10) opposing each other across the gate electrode 5 of the memory cell is extended in the right/left directions of this paper in FIG. 20B as a source line SL which connects adjacent memory cells.

According to the seventh embodiment, since the memory cell is NOR connected, in addition to the effects of the first to the fourth embodiments, a large cell current is secured and high-speed data readout is achieved.

In the meantime, the present invention is not restricted to the above-described embodiments, however may be modified in various ways. For example to form the device isolating film or the insulation film, it is permissible to employ not only the method of converting silicon to a silicon oxide film or silicon nitride film but also a method of implanting oxygen ions into a deposited silicon or a method of oxidizing a deposited silicon. Further, the electric charge accumulating layer 3 may be composed of TiO₂, Al₂O₃, tantalum oxide, strontium titanate, barium titanate, zirconium titanate or multi-layered film thereof.

Although the case where the p-type silicon substrate is used as the semiconductor substrate has been described, it is permissible to use the n-type silicon substrate, SOI silicon layer of the SOI substrate, or mono-crystal semiconductor substrate containing silicon such as SiGe mixed crystal, SiGeC mixed crystal or the like instead.

Further, although the case where the n-type MONOS-FET is formed in the p-type well has been described, the p-type MONOS-FET may be formed in the n-type well. In this case, the type n of the source/drain region and each semiconductor region of each embodiment is replaced with type p and the type p is replaced with the type n. Further, the doping impurity As, P, Sb is replaced with any one of In and B. At this moment, the p-type impurity is doped to the gate electrode of the memory cell.

The gate electrode 5 may be composed of a Si semiconductor, SiGe mixed crystal or SiGeC mixed crystal, or polycrystalline silicon or multi-layered structure. The gate electrode 5 may be composed of amorphous Si, amorphous SiGe mixed crystal or amorphous SiGeC mixed crystal as well as the above-described material or constituted of layered structure of these materials. Preferably, the gate electrode 5 is composed of a semiconductor, particularly a semiconductor containing Si so as to form a p-type gate and prevent implantation of electrons from the gate electrode. Further, the electric charge accumulating layer 3 may be formed in the form of dots and in that case, needless to say, the present invention can be applied.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory cell allowing information to be written or erased electrically, said semiconductor memory cell comprising:
a first insulation layer;
an electric charge accumulating layer including an insulating material;
a second insulation layer including a silicon oxide film or a silicon oxynitride film, and being more than 5 nm in thickness; and
a control electrode formed on said second insulating layer and included a p-type semiconductor containing p-type impurity.

2. The semiconductor memory cell according to claim 1, wherein said first insulating layer including a silicon oxide film or a silicon oxynitride film, and the thickness of said second insulating layer is at least 1.8 nm larger than that of said first insulating layer.

3. The semiconductor memory cell according to claim 1, wherein said control electrode including silicon and the amount of said silicon is the largest of the plurality of elements contained in said control electrode.

4. The semiconductor memory cell according to claim 1, wherein a density of said p-type impurity of said control electrode is more than 2×10¹⁹ (cm⁻³) and less than 1×10²⁰ (cm⁻³).

5. A semiconductor memory cell allowing information to be written or erased electrically, said semiconductor memory cell comprising:
a gate insulation film having a multi-layer structure including three layers, said gate insulation film being included a first insulation layer, an electric charge accumulating layer and a second insulation layer, said electric charge accumulating layer being included a silicon nitride film or a silicon oxynitride film, said first insulation layer and second insulation layer being included a silicon oxide film or a silicon oxynitride film containing more oxygen composition than said electric charge accumulating layer, said second insulation layer being more than 5 nm in thickness; and
a control electrode formed on said gate insulation film and included a p-type semiconductor containing p-type impurity.

6. The semiconductor memory cell according to claim 5, wherein the thickness of said second insulation layer is at least 1.8 nm larger than that of said first insulation layer.

7. The semiconductor memory cell according to claim 5, wherein said control electrode contains a plurality of elements including silicon and the amount of said silicon is the largest of the plurality of elements contained in said control electrode.

8. The semiconductor memory cell according to claim 5, wherein a density of said p-type impurity of said control electrode is more than 2×10¹⁹ (cm⁻³) and less than 1×10²⁰ (cm⁻³).

9. A semiconductor memory device comprising:
a semiconductor memory cell constituted of an electric field effect transistor allowing information to be written or erased electrically, said semiconductor memory cell having:
a source region and a drain region each of a second conductive type formed in a semiconductor region of a first conductive type;
a gate insulation film formed on said semi-conductor region, said gate insulation film having a multi-layer structure including three layers, said gate insulation film being included a first insulation film, an electric charge accumulating layer and a second insulation layer, said electric charge accumulating layer being included a silicon oxide film or a silicon oxynitride film, said first insulation layer and second insulation layer being included a silicon oxide film or a silicon oxynitride film containing more oxygen composition than said electric charge accumulating layer, said second insulation layer being more than 5 nm in thickness; and
a control electrode formed on said gate insulation film and included a p-type semiconductor containing p-type impurity,
wherein said electric field effect transistor has an operation mode for, by applying a voltage which makes the voltage of the control electrode negative with respect to said source region or drain region to between said source region or said drain region and said control electrode so as to supply current between said source region or drain region and said electric charge accumulating layer, setting a threshold value of said electric field effect transistor more negative.

10. The semiconductor memory device according to claim 9, wherein when the voltage of said control electrode with respect to the potential of at least any one of said source region and said drain region is Vpp (V), assuming that the total film thickness of said gate insulation film, obtained by converting based on the silicon oxide film is teff (nm), the value of said voltage Vpp is set so as to satisfy −1.0×teff<Vpp<−0.7×teff−1.

11. The semiconductor memory device according to claim 9, wherein when the voltage of said control electrode with respect to the potential of at least any one of said source region or said drain region is Vpp (V), assuming that the thickness of said first insulation layer is tox1 (nm), the thickness of the electric charge accumulating layer is tN (nm) and the thickness of the second insulation layer is tox2 (nm), the value of said voltage Vpp is set so as to satisfy −1.0×(tox1+tN/2+tox2)<Vpp<−0.7×(tox1+tN/2+tox2)−1.

12. The semiconductor memory device according to claim 9, wherein the thickness of said second insulation layer is at least 1.8 nm larger than that of said first insulation layer.

13. A semiconductor memory device comprising:
a semiconductor memory cell constituted of a field effect transistor allowing information to be written or erased electrically, said semiconductor memory cell having:
a source region and a drain region each of a second conductive type formed in a semiconductor region of a first conductive type;
a gate insulation film formed on said semi-conductor region, said gate insulation film having a multi-layer structure including three layers, said gate insulation film being included a first insulation film, an electric charge accumulating layer and a second insulation layer, said electric charge accumulating layer being included a silicon oxide film or a silicon oxynitride film, said first insulation layer and second insulation layer being included a silicon oxide film or a silicon oxynitride film containing more oxygen composition than said electric charge accumulating layer, said second insulation layer being more than 5 nm in thickness; and
a control electrode formed on said gate insulation film and included a p-type semiconductor containing p-type impurity,
wherein said electric field effect transistor has such an operation mode for, by applying a voltage which makes the voltage of the control electrode negative with respect to said semiconductor region to between said semiconductor region and said control electrode so as to supply current between said semiconductor region and said electric charge accumulating layer, setting the threshold value of said electric field effect transistor more negative.

14. The semiconductor memory device according to claim 13, wherein when the voltage of said control electrode with respect to the potential of said semiconductor region is Vpp (V), assuming that the total film thickness of said gate insulation film, obtained by converting based on the silicon oxide film is teff (nm), the value of said voltage Vpp is set so as to satisfy −1.0×teff<Vpp<−0.7×teff−1.

15. The semiconductor memory device according to claim 13, wherein when the voltage of said control electrode with respect to the potential of said semiconductor region is Vpp (V), assuming that the thickness of said first insulation layer is tox1 (nm), the thickness of the electric charge accumulating layer is tN (nm) and the thickness of the second insulation layer is tox2 (nm), the value of said voltage Vpp is set so as to satisfy −1.0×(tox1+tN/2+tox2)<Vpp<−0.7×(tox1+tN/2+tox2)−1.

16. The semiconductor memory device according to claim 13, wherein when said operation mode is selected, direct tunnel current or Fowler-Nordheim tunnel current is supplied between said semiconductor region and said electric charge accumulating layer.

17. The semiconductor memory device according to claim 13, wherein when said operation mode is selected, direct tunnel current is supplied between said semiconductor region and said electric charge accumulating layer.

18. The semiconductor memory device according to claim 13, wherein the thickness of said second insulation layer is at least 1.8 nm larger than that of said first insulation layer.

19. A semiconductor memory device comprising:
at least one memory cell unit including a plurality of electric field effect transistors connected in series,
a pair of select transistors connected to an end and the other end of said at least one memory cell unit; and
a data transmission line connected to one of said pair of select transistors,
wherein each of said plurality of field effect transistors including:
a source region and a drain region each of a second conductive type formed in a semiconductor region of a first conductive type;
a gate insulation film formed on said semiconductor region, said gate insulation film having a multi-layer structure including three layers, said gate insulation film being included a first insulation film, an electric charge accumulating layer and a second insulation layer, said electric charge accumulating layer being included a silicon oxide film or a silicon oxynitride film, said first insulation layer and second insulation layer being included a silicon oxide film or a silicon oxynitride film containing more oxygen composition than said electric charge accumulating layer, said second insulation layer being more than 5 nm in thickness; and
a control electrode formed on said gate insulation film and included a p-type semiconductor containing p-type impurity.

20. The semiconductor memory device according to claim 19, wherein the thickness of said second insulation layer is at least 1.8 nm larger than that of said first insulation layer.

21. The semiconductor memory device according to claim 19, wherein a density of said p-type impurity of said control electrode is more than 2×10¹⁹ (cm⁻³) and less than 1×10²⁰ (cm⁻³).

22. The semiconductor memory device according to claim 19, wherein each of said pair of select transistors has a control electrode, said control electrode of select transistor composed of a p-type semiconductor containing p-type impurity.

23. The semiconductor memory device according to claim 19, wherein said at least one memory cell unit comprises a plurality of memory cell units,
said semiconductor memory device further comprising;
a plurality of data transmission lines:
a plurality of data select lines disposed so as to intersect said plurality of data transmission lines, and connected to said control electrode of said plurality of electric field effect transistors; and
a pair of control lines disposed in parallel to said plurality of data select lines, said pair of control lines supplying a control signal to said pair of select transistors,
wherein said plurality of memory cell units being disposed in parallel to each other in a direction intersecting said plurality of data transmission lines.

24. A semiconductor memory device comprising a semiconductor memory cell constituted of a field effect transistor allowing information to be written or erased electrically, said semiconductor memory cell having:
a source region and a drain region each of a second conductive type formed in a semiconductor region of a first conductive type;
a gate insulation film formed on said semiconductor region, said gate insulation film having a multi-layer structure including three layers, said gate insulation film being included a first insulation film, an electric charge accumulating layer and a second insulation layer, said electric charge accumulating layer being included a silicon oxide film or a silicon oxynitride film, said first insulation layer and second insulation layer being included a silicon oxide film or a silicon oxynitride film containing more oxygen composition than said electric charge accumulating layer, said second insulation layer being more than 5 nm in thickness; and
a control electrode formed on said gate insulation film and included a p-type semiconductor containing p-type impurity,
wherein said electric field effect transistor has such an operation mode for, by applying a voltage which makes the voltage of the control electrode negative with respect to said source region or drain region to between said source region or said drain region and said control electrode so as to supply current between said source region or drain region and said electric charge accumulating layer, setting the threshold value of said electric field effect transistor more negative, and
when the voltage of said control electrode with respect to the potential of said source region or drain region is Vpp (V), assuming that the total film thickness of said gate insulation film, obtained by converting based on the silicon oxide film is teff (nm), the value of said voltage Vpp is set so as to satisfy −1.0×teff<Vpp<−0.7×teff−1.

25. The semiconductor memory device according to claim 24, wherein when the voltage of said control electrode with respect to the potential of said source region or drain region is Vpp (V), assuming that the thickness of said first insulation layer is tox1 (nm), the thickness of the electric charge accumulating layer is tN (nm) and the thickness of the second insulation layer is tox2 (nm), the value of said voltage Vpp is set so as to satisfy −1.0×(tox1+tN/2+tox2)<Vpp<−0.7×(tox1+tN/2+tox2)−1.

26. The semiconductor memory device according to claim 24, wherein when said operation mode is selected, hot hole current is supplied between said source region or drain region and said electric charge accumulating layer.

27. The semiconductor memory device according to claim 24, wherein the thickness of said second insulation layer is at least 1.8 nm larger than that of said first insulation layer.

28. The semiconductor memory cell according to claim 24, wherein a density of said p-type impurity of said control electrode is 2×10¹⁹ (cm⁻³) or more and less than 1×10²⁰ (cm⁻³).

29. A semiconductor memory device comprising:
a first semiconductor region of a first conductivity type formed in a semiconductor substrate;
a memory cell transistor formed in said first semiconductor region allowing information to be written or erased electrically;
a second semiconductor region of a second conductivity type formed in said semiconductor substrate; and
a transistor formed in said second semiconductor region,
wherein said memory cell transistor having:
a first source region and a first drain region each of a second conductivity type formed in said first semiconductor region;
a gate insulation film formed on said first semiconductor region and having a multi-layer structure including three layers, said gate insulation film being included a first insulation layer, an electric charge accumulating layer and a second insulation layer, said electric charge accumulating layer being included a silicon nitride film or a silicon oxynitride film, said first insulation layer and second insulation layer being included a silicon oxynitride film containing a larger oxygen content than silicon oxide film or said electric charge accumulating layer, said second insulation layer being more than 5 nm in thickness, said first control electrode containing p-type impurity; and
a first control electrode formed on said gate insulation film,
wherein said transistor having:
a second source region and a second drain region each of said first conductivity type formed in said second semiconductor region; and
a second control electrode formed on said second semiconductor region through a third insulation layer and containing the p-type impurity.

30. The semiconductor memory device according to claim 29, wherein the thickness of said second insulation layer is at least 1.8 nm larger than that of said first insulation layer.

31. The semiconductor memory device according to claim 29, wherein a density of the p-type impurity in said first and second control electrodes is 2×10¹⁹ (cm⁻³) or more and less than 1×10²⁰ (cm⁻³), respectively.

32. The semiconductor memory device according to claim 29, wherein said third insulation layer is included a silicon oxide film which is less than 20 nm in thickness.

33. The semiconductor memory device according to claim 29, wherein said first control electrode and second control electrode have a multi-layer structure of metallic silicide and semiconductor, respectively.
